(19) United States
(12) Patent Application Publication
(10) Pub. No.: US 2025/0357452 A1
(43) Pub. Date: Nov. 20, 2025

(54) SEMICONDUCTOR PACKAGE

(71) Applicant: SAMSUNG ELECTRONICS CO., LTD., Suwon-si (KR)

(72) Inventors: Jing Cheng LIN, Suwon-si (KR); Youngkun JEE, Suwon-si (KR)

(73) Assignee: SAMSUNG ELECTRONICS CO., LTD., Suwon-si (KR)

(21) Appl. No.: 18/977,459

(22) Filed: Dec. 11, 2024

(30) Foreign Application Priority Data
May 17, 2024 (KR) 10-2024-0064806

(51) Int. Cl. H01L 25/18; H01L 23/00; H01L 23/31; H10B 80/00

(52) U.S. Cl. CPC H01L 25/18; H01L 23/3135; H01L 24/05; H01L 24/08; H10B 80/00; H01L 2224/05578; H01L 2224/05647; H01L 2224/05686; H01L 2224/08146; H01L 2225/06541; H01L 2225/06555; H01L 2924/1431; H01L 2924/1436; H01L 2924/35121

(57) ABSTRACT

A semiconductor package includes: a first semiconductor chip including a first semiconductor substrate and a plurality of first through-electrodes passing through the first semiconductor substrate; a plurality of second semiconductor chips stacked on the first semiconductor chip, each of the plurality of second semiconductor chips including a second semiconductor substrate and a plurality of second through-electrodes passing through the second semiconductor substrate; a third semiconductor chip between the first semiconductor chip and one of the plurality of second semiconductor chips, the third semiconductor chip including a third semiconductor substrate and a plurality of third through-electrodes passing through the third semiconductor substrate; and a side support layer within a space between the third semiconductor chip and the first semiconductor chip, wherein a first horizontal width of the third semiconductor chip is different from first horizontal widths of the plurality of second semiconductor chips.

### CROSS-REFERENCE TO RELATED APPLICATION

This application is based on and claims priority under 35 U.S.C. § 119 to Korean Patent Application No. 10-2024-0064806, filed on May 17, 2024, in the Korean Intellectual Property Office, the disclosure of which is incorporated by reference herein in its entirety.

### BACKGROUND

### 1. Field

Embodiments of the present disclosure relate to a semiconductor package, and particularly, to a semiconductor package including stacked semiconductor chips.

### 2. Brief Description of Related Art

As electronic products are required to be smaller, larger in capacity, and

higher in performance, high integration and high speed of semiconductor packages are also required. For this purpose, a semiconductor package including a plurality of stacked semiconductor chips is being developed.

### SUMMARY

According to embodiments of the present disclosure, a semiconductor package including stacked semiconductor chips and with improved structural reliability may be provided.

According to embodiments of the present disclosure, a semiconductor package may be provided and include: a first semiconductor chip including a first semiconductor substrate and a plurality of first through-electrodes passing through the first semiconductor substrate; a plurality of second semiconductor chips stacked on the first semiconductor chip, each of the plurality of second semiconductor chips including a second semiconductor substrate and a plurality of second through-electrodes passing through the second semiconductor substrate; a third semiconductor chip between the first semiconductor chip and one of the plurality of second semiconductor chips, the third semiconductor chip including a third semiconductor substrate and a plurality of third through-electrodes passing through the third semiconductor substrate; and a side support layer within a space between the third semiconductor chip and the first semiconductor chip, wherein a first horizontal width of the third semiconductor chip is different from first horizontal widths of the plurality of second semiconductor chips.

According to embodiments of the present disclosure, a semiconductor package may be provided and include: a high bandwidth memory (HBM) control die including a first semiconductor substrate and a plurality of first through-electrodes passing through the first semiconductor substrate; a plurality of first dynamic random access memory (DRAM) dies stacked on the HBM control die, each of the plurality of first DRAM dies including a second semiconductor substrate and a plurality of second through-electrodes passing through the second semiconductor substrate, and horizontal widths of the plurality of first DRAM dies are the same as each other; a second DRAM die between the HBM control die and one of the plurality of first DRAM dies, the second DRAM die including a third semiconductor substrate and a plurality of third through-electrodes passing through the third semiconductor substrate, and a horizontal width of the second DRAM die is greater than the horizontal widths of the plurality of first DRAM dies; a plurality of bonding pads between the HBM control die, each of the plurality of first DRAM dies, and the second DRAM die, and electrically connecting the plurality of first through-electrodes, the plurality of second through-electrodes, and the plurality of third through-electrodes to each other; a plurality of chip bonding insulating layers surrounding the plurality of bonding pads and between the HBM control die, the plurality of first DRAM dies, and the second DRAM die; and a side support layer on least a part of a side surface of the second DRAM die.

According to embodiments of the present disclosure, a semiconductor package may be provided and include: an HBM control die including a first semiconductor substrate and a plurality of first through-electrodes passing through the first semiconductor substrate; a plurality of first DRAM dies stacked on the HBM control die, each of the plurality of first DRAM dies including a second semiconductor substrate and a plurality of second through-electrodes passing through the second semiconductor substrate, and horizontal widths of the plurality of first DRAM dies are the same as each other; a second DRAM die between the HBM control die and a lowermost first DRAM die among the plurality of first DRAM dies, the second DRAM die including a third semiconductor substrate and a plurality of third through-electrodes passing through the third semiconductor substrate, and a horizontal width of the second DRAM die is less than the horizontal widths of the plurality of first DRAM dies; a plurality of bonding pads between the HBM control die, each of the plurality of first DRAM dies, and the second DRAM die, and electrically connecting the plurality of first through-electrodes, the plurality of second through-electrodes, and the plurality of third through-electrodes to each other; a plurality of chip bonding insulating layers surrounding the plurality of bonding pads and between the HBM control die, the plurality of first DRAM dies, and the second DRAM die; and a side support layer within a space between the lowermost first DRAM die and the HBM control die.

### BRIEF DESCRIPTION OF DRAWINGS

Embodiments of the present disclosure will be more clearly understood from the following detailed description taken in conjunction with the accompanying drawings in which:

FIG. 1 is a plan view of a semiconductor package according to an embodiment;

FIG. 2 is a cross-sectional view taken along a line A-A′ in FIG. 1;

FIG. 3 is an enlarged view of a region CX1 in FIG. 2;

FIGS. 4, 5, and 6 are enlarged views of semiconductor packages according to embodiments and are enlarged views corresponding to FIG. 3;

FIG. 7 is a plan view of a semiconductor package according to an embodiment;

FIGS. 8, 9, 10, and 11 are cross-sectional views of semiconductor packages according to embodiments;

FIGS. 12 to 20 are cross-sectional views sequentially illustrating manufacturing processes of a semiconductor package according to an embodiment;

FIGS. 21 to 26 are cross-sectional views sequentially illustrating manufacturing processes of a semiconductor package according to an embodiment; and

FIG. 27 is a block diagram schematically showing a configuration of a semiconductor package according to an embodiment.

### DETAILED DESCRIPTION

Hereinafter, non-limiting example embodiments of the present disclosure are described in detail with reference to the accompanying drawings. However, embodiments of the present disclosure are not limited to the example embodiments described below, and may be embodied in various other forms. The following example embodiments are provided to fully describe the scope of the present disclosure to those skilled in the art to which the present disclosure belongs.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

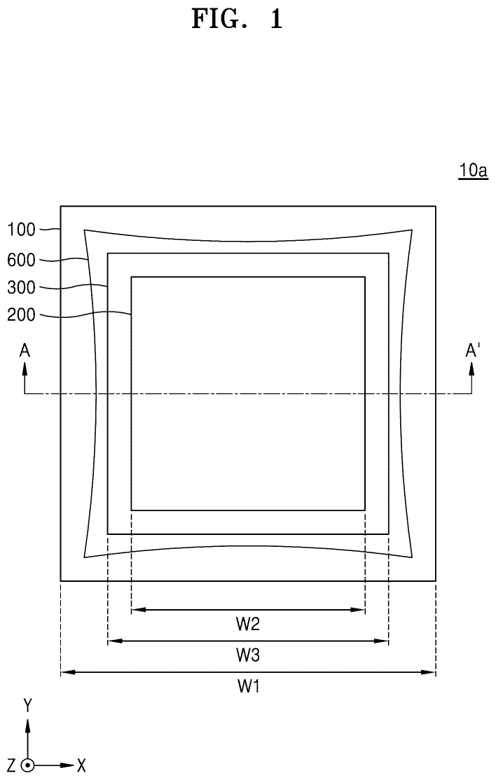

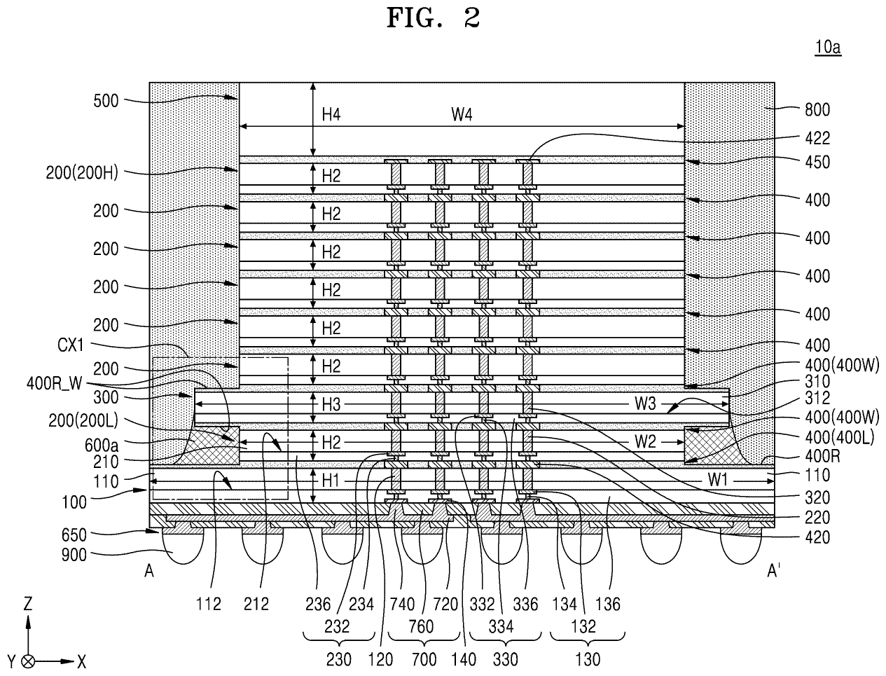

FIG. 1 is a plan view of a semiconductor package 10a according to an embodiment, and FIG. 2 is a cross-sectional view taken along a line A-A′ of FIG. 1.

Referring to FIGS. 1 and 2, the semiconductor package 10a may include a first semiconductor chip 100, a plurality of second semiconductor chips 200 stacked in a vertical direction (the Z direction), and a third semiconductor chip 300. FIG. 2 illustrates that the total number of the plurality of second semiconductor chips 200 and the third semiconductor chip 300 included in the semiconductor package 10a is 8, but the total number is not limited thereto. For example, in some embodiments, the sum of the number of the plurality of second semiconductor chips 200 and the third semiconductor chip 300 may be a multiple of 4. The plurality of second semiconductor chips 200 may be sequentially stacked on the first semiconductor chip 100. For the sake of convenience of description, the second semiconductor chip 200 at the bottom of the plurality of second semiconductor chips 200 is called a lowermost second semiconductor chip 200L, and the second semiconductor chip 200 at the top of the plurality of second semiconductor chips 200 is called an uppermost second semiconductor chip 200H. In the present disclosure, a direction orthogonal to an upper surface of the first semiconductor chip 100 may be defined as a vertical direction (the Z direction), and a direction which is parallel to the upper surface of the first semiconductor chip 100 and in which a plurality of first through-electrodes 120 are sequentially arranged may be defined as a first horizontal direction (the X direction). Also, a direction perpendicular to the first horizontal direction (the X direction) may be defined as a second horizontal direction (the Y direction).

According to one embodiment, the third semiconductor chip 300 may be spaced apart from the first semiconductor chip 100 in the vertical direction (the Z direction) with the lowermost second semiconductor chip 200L between the first semiconductor chip 100 and the third semiconductor chip 300.

The semiconductor package 10a may include a plurality of bonding pads 420 between the first semiconductor chip 100, the plurality of second semiconductor chips 200, and the third semiconductor chip 300. The first semiconductor chip 100, the plurality of second semiconductor chips 200, and the third semiconductor chip 300 may be electrically connected to each other, exchange signals, and provide power and ground through the plurality of bonding pads 420. For example, the plurality of bonding pads 420 may be between the first semiconductor chip 100 and the lowermost second semiconductor chip 200L, between the lowermost second semiconductor chip 200L and the third semiconductor chip 300, between the third semiconductor chip 300 and the second semiconductor chip 200 that is directly above the third semiconductor chip 300 in the Z direction, and between adjacent ones of the second semiconductor chips 200. For example, the plurality of bonding pads 420 may be formed of a material including Cu.

The first semiconductor chip 100 may include a first semiconductor substrate 110 having active and inactive surfaces opposite to each other, a first semiconductor element (e.g., a first semiconductor device 112) formed on the active surface of the first semiconductor substrate 110, a first wiring structure 130 formed on the active surface of the first semiconductor substrate 110, and a plurality of first through-electrodes 120 connected to the first wiring structure 130 and passing through at least a part of the first semiconductor chip 100. The first semiconductor chip 100 may further include a plurality of chip pads 140 which are at (e.g., in or on) a lower surface of the first semiconductor chip 100 and are electrically connected to a first wiring pattern 132 and/or a first wiring via 134 of the first wiring structure 130. The plurality of chip pads 140 may be electrically connected to the first semiconductor device 112 or the first wiring structure 130 through the first wiring pattern 132 and/or the first wiring via 134.

Within the semiconductor package 10a, the first semiconductor chip 100 may be arranged such that the active surface of the first semiconductor substrate 110 faces downward and the inactive surface of the first semiconductor substrate 110 faces upward. Accordingly, unless otherwise stated in the specification, an upper surface of the first semiconductor chip 100 included in the semiconductor package 10a refers to a surface that faces in the same direction as a facing direction of the inactive surface of the first semiconductor substrate 110, and a lower surface of the first semiconductor chip 100 refers to a surface that faces in the same direction as a facing direction of the active surface of the first semiconductor substrate 110. Also, in describing the first semiconductor chip 100, the lower surface of the first semiconductor chip 100 (which faces in the same direction as the active surface of the first semiconductor substrate 110) may be referred to as a front surface of the first semiconductor chip 100, and the upper surface of the first semiconductor chip 100 (which faces in the same direction as the inactive surface of the first semiconductor substrate 110) may be referred to as a rear surface of the first semiconductor chip 100.

Each of the plurality of second semiconductor chips 200 may include a second semiconductor substrate 210 having active and inactive surfaces opposite to each other, a second semiconductor element (e.g., a second semiconductor device 212) formed on the active surface of the second semiconductor substrate 210, and a second wiring structure 230 formed on the active surface of the second semiconductor substrate 210.

Each of the plurality of second semiconductor chips 200 may further include a plurality of second through-electrodes 220 connected to the second wiring structure 230 and penetrating at least a part of the second semiconductor chip 200. Among the plurality of second semiconductor chips 200, the uppermost second semiconductor chip 200H, which is the second semiconductor chip 200 farthest away from the first semiconductor chip 100 and located at the top of the semiconductor package 10a, may not include the plurality of second through-electrodes 220.

In some embodiments, a second vertical height H2, that is a thickness of the uppermost second semiconductor chip 200H, may be almost equal to second vertical heights H2 that are thicknesses of the other second semiconductor chips 200.

Within the semiconductor package 10a, the plurality of second semiconductor chips 200 may be sequentially stacked in the vertical direction (the Z direction) over the first semiconductor chip 100 while active surfaces of the plurality of second semiconductor chips 200 face downward (e.g., toward the first semiconductor chip 100). Accordingly, unless otherwise stated in the specification, an upper surface of the second semiconductor chip 200 included in the semiconductor package 10a refers to a surface that faces in the same facing direction as an inactive surface of the second semiconductor substrate 210, and a lower surface of the second semiconductor chip 200 included in the semiconductor package 10a refers to a surface that faces in the same facing direction as an inactive surface of the second semiconductor substrate 210. Also, in describing the second semiconductor chip 200, the lower surface of the second semiconductor chip 200 (which faces in the same direction as the active surface of the second semiconductor substrate 210) may be referred to as a front surface of the second semiconductor chip 200, and the upper surface of the second semiconductor chip 200 (that faces in the same direction as the inactive surface of the second semiconductor chip 200) may be referred to as a rear surface of the second semiconductor chip 200.

The third semiconductor chip 300, which is spaced apart from the first semiconductor chip 100 in the vertical direction (the Z direction) with the lowermost second semiconductor chip 200L between the first semiconductor chip 100 and the third semiconductor chip 300, may include a third semiconductor substrate 310 having active and inactive surfaces opposite to each other, a third semiconductor element (e.g., a third semiconductor device 312) formed on the active surface of the third semiconductor substrate 310, a third wiring structure 330 formed on the active surface of the third semiconductor substrate 310, and a plurality of third through-electrodes 320 connected to the third wiring structure 330 and passing through at least a part of the third semiconductor chip 300. Compared to the second semiconductor chip 200, the third semiconductor chip 300 may have substantially the same function and structure as the second semiconductor chip 200 except that the third semiconductor chip 300 may have a different horizontal width in a lateral direction (the X direction and/or Y direction).

Like the second semiconductor chip 200, an upper surface of the third semiconductor chip 300 refers to a surface that faces in the same direction as a facing direction of the inactive surface of the third semiconductor substrate 310, and a lower surface of the third semiconductor substrate 310 refers to a surface that faces in the same direction as a facing direction of the active surface of the third semiconductor substrate 310. Also, in describing the third semiconductor chip 300, the lower surface of the third semiconductor chip 300 (that faces in the same direction as the active surface of the third semiconductor substrate 310) may be referred to as a front surface of the third semiconductor chip 300, and the upper surface of the third semiconductor chip 300 (that faces in the same direction as the inactive surface of the third semiconductor chip 300) may be referred to as a rear surface of the third semiconductor chip 300.

The first semiconductor substrate 110, the second semiconductor substrate 210, and the third semiconductor substrate 310 may include a semiconductor material, such as silicon (Si). Also, the first semiconductor substrate 110, the second semiconductor substrate 210, and the third semiconductor substrate 310 may include a semiconductor material, such as germanium (Ge). Each of the first semiconductor substrate 110, the second semiconductor substrate 210, and the third semiconductor substrate 310 may have an active surface and an inactive surface opposite to the active surface. Each of the first semiconductor substrate 110, the second semiconductor substrate 210, and the third semiconductor substrate 310 may include a conductive region (e.g., a well doped with an impurity). Each of the first semiconductor substrate 110, the second semiconductor substrate 210, and the third semiconductor substrate 310 may have various device isolation structures, such as a shallow trench isolation (STI) structure.

Each of the first semiconductor device 112, the second semiconductor device 212, and the third semiconductor device 312 may include a plurality of individual devices of various types. The plurality of individual devices may include various microelectronic devices such as, for example, a metal-oxide-semiconductor field effect transistor (MOSFET) such as a complementary metal-oxide-semiconductor (CMOS) transistor, a system large scale integration (LSI), an image sensor such as CMOS imaging sensor (CIS), a micro-electro-mechanical system (MEMS), an active element, a passive element, and so on. The plurality of individual devices may be electrically connected to a conductive region of the first semiconductor substrate 110, the second semiconductor substrate 210, or the third semiconductor substrate 310. Each of the first semiconductor device 112, the second semiconductor device 212, and the third semiconductor device 312 may further include at least two from among the plurality of individual devices, or a conductive wire or a conductive plug electrically connecting the conductive regions of the plurality of individual devices, the first semiconductor substrate 110, the second semiconductor substrate 210, and the third semiconductor substrate 310 to each other. Also, each of the plurality of individual devices may be electrically separated from other adjacent individual devices by an insulating layer.

At least one from among the first semiconductor chip 100, the second semiconductor chip 200, and the third semiconductor chip 300 may be a memory semiconductor chip. In some embodiments, the first semiconductor chip 100 may include a serial-parallel conversion circuit and may be a buffer chip for controlling the plurality of second semiconductor chips 200 and the third semiconductor chip 300, and the plurality of second semiconductor chips 200 and the third semiconductor chip 300 may be memory chips including memory cells. For example, the semiconductor package 10a including the first semiconductor chip 100, the plurality of second semiconductor chips 200, and the third semiconductor chip 300 may be a high bandwidth memory (HBM), the first semiconductor chip 100 may be referred to as an HBM control die, and each of the plurality of second semiconductor chips 200 and the third semiconductor chips 300 may be referred to as a dynamic random access memory (DRAM) die.

The first wiring structure 130 may include a plurality of first wiring patterns 132, a plurality of first wiring vias 134 respectively connected to the plurality of first wiring patterns 132, and a first inter-wiring insulating layer 136 surrounding the plurality of first wiring patterns 132 and the plurality of first wiring vias 134. In some embodiments, the plurality of first wiring patterns 132 may each have a thickness of about 0.5 micrometer or less. In some embodiments, the first wiring structure 130 may have a multi-layer wiring structure including the plurality of first wiring patterns 132 and the plurality of first wiring vias 134 at different vertical levels.

The second wiring structure 230 may include a plurality of second wiring patterns 232, a plurality of second wiring vias 234 respectively connected to the plurality of second wiring patterns 232, and a second inter-wiring insulating layer 236 surrounding the plurality of second wiring patterns 232 and the plurality of second wiring vias 234. In some embodiments, the plurality of second wiring patterns 232 may each have a thickness of about 0.5 micrometer or less. In some embodiments, the second wiring structure 230 may have a multi-layer wiring structure including the plurality of second wiring patterns 232 and the plurality of second wiring vias 234 at different vertical levels.

In addition, the third wiring structure 330 may also include a plurality of third wiring patterns 332, a plurality of third wiring vias 334 respectively connected to the plurality of third wiring patterns 332, and a third inter-wiring insulating layer 336 surrounding the plurality of third wiring patterns 332 and the plurality of third wiring vias 334. In some embodiments, the plurality of third wiring patterns 332 may each have a thickness of about 0.5 micrometer or less. In some embodiments, the third wiring structure 330 may have a multi-layer wiring structure including the plurality of third wiring patterns 332 and the plurality of third wiring vias 334 at different vertical levels.

The plurality of first wiring patterns 132, the plurality of first wiring vias 134, the plurality of second wiring patterns 232, the plurality of second wiring vias 234, the plurality of third wiring patterns 332, and the plurality of third wiring vias 334 may each include a metal material, such as aluminum, copper, or tungsten. In some embodiments, the plurality of first wiring patterns 132, the plurality of first wiring vias 134, the plurality of second wiring patterns 232, the plurality of second wiring vias 234, the plurality of third wiring pattern 332, and the plurality of third wiring vias 334 may each include a wiring barrier layer and a wiring metal layer. The wiring barrier layer may include metal, metal nitride, or an alloy. The wiring metal layer may include at least one metal selected from W, Al, Ti, Ta, Ru, Mn, and Cu.

When each of the first wiring structure 130, the second wiring structure 230, and the third wiring structure 330 has a multi-layer wiring structure, the first inter-wiring insulating layer 136, the second inter-wiring insulating layer 236, and the third inter-wiring insulating layer 336 may each have a multi-layer structure in which a plurality of insulating layers are stacked and which corresponds to the multi-layer wiring structure of each of the first wiring structure 130, the second wiring structure 230, and the third wiring structure. For example, the first inter-wiring insulating layer 136, the second inter-wiring insulating layer 236, and the third inter-wiring insulating layer 336 may include silicon oxide, silicon nitride, silicon oxynitride, an insulating material with a dielectric constant lower than a dielectric constant of the silicon oxide, or a combination thereof. In some embodiments, the first inter-wiring insulating layer 136, the second inter-wiring insulating layer 236, and the third inter-wiring insulating layer 336 may include a tetraethyl orthosilicate (TEOS) film or an ultralow K (ULK) film with an ultralow dielectric constant (K) of about 2.2 to 2.4. The ULK film may include a SiOC film or a SiCOH film.

The first through-electrode 120, the second through-electrode 220, and the third through-electrode 320 may each include a through silicon via (TSV). The first through-electrode 120, the second through-electrode 220, and the third through-electrode 320 may each include a conductive plug passing through the first semiconductor substrate 110, the second semiconductor substrate 210, and the third semiconductor substrate 310, respectively, and a conductive barrier film surrounding the conductive plug. The conductive plug may have a cylindrical shape, and the conductive barrier film may have a cylindrical shape surrounding a sidewall of the conductive plug. A via insulating layer may be between the first through-electrode 120 and the first semiconductor substrate 110, between the second through-electrode 220 and the second semiconductor substrate 210, and between the third through-electrode 320 and the third semiconductor substrate 310 to surround side walls of the first through-electrode 120, the second through-electrode 220, and the third through-electrode 320. The first through-electrode 120, the second through-electrode 220, and the third through-electrode 320 may each have a via-first structure, a via-middle structure, or a via-last structure.

The first semiconductor chip 100 may have a first horizontal width W1 and a first vertical height H1, and each of the plurality of second semiconductor chips 200 may have a second horizontal width W2 and a second vertical height H1, and the third semiconductor chip 300 may have a third horizontal width W3 and a third vertical height H3. In some embodiments, the first horizontal width W1 may be greater than the third horizontal width W3, and the third horizontal width W3 may be greater than the second horizontal width W2. The first semiconductor chip 100, the plurality of second semiconductor chips 200, and the third semiconductor chip 300 may be stacked such that centers thereof overlap each other in the vertical direction (the Z direction). Accordingly, from a horizontal perspective, opposite edges of the first semiconductor chip 100 may protrude from both edges of the third semiconductor chip 300 in a first horizontal direction (the X direction), and opposite edges of the third semiconductor chip 300 may protrude from both edges of each of the plurality of second semiconductor chips 200 in the first horizontal direction (the X direction).

In some embodiments, the first vertical height H1, the second vertical height H2, and the third vertical height H3 may have substantially the same value as each other. For example, the first vertical height H1, the second vertical height H2, and the third vertical height H3 may be about 50 micrometers to about 70 micrometers.

The plurality of bonding pads 420 may respectively and electrically connect the plurality of second wiring patterns 232 and/or the plurality of second wiring vias 234 of the second wiring structure 230 to the plurality of first through-electrodes 120 or the plurality of second through-electrodes 220 located below the second wiring structure 230.

For example, the plurality of second wiring patterns 232 and/or the plurality of second wiring vias 234 of the second wiring structure 230 included in the lowermost second semiconductor chip 200L may be respectively and electrically connected to the plurality of first through-electrodes 120 included in the first semiconductor chip 100, located below the lowermost second semiconductor chip 200L, through some of the plurality of bonding pads 420 that are a plurality of first bonding pads. Also, the plurality of second wiring patterns 232 and/or the plurality of second wiring vias 234 of the second wiring structure 230 included in a second semiconductor chip 200, other than the lowermost second semiconductor chip 200L, may be respectively and electrically connected to the plurality of second through-electrodes 220 included in another second semiconductor chip 200, located below the second semiconductor chip 200, through some of the plurality of bonding pads 420 that are a plurality of second bonding pads.

In addition to this, some of the plurality of bonding pads 420 may respectively and electrically connect the plurality of third wiring patterns 332 and/or the plurality of third wiring vias 334 of the third wiring structure 330 to the plurality of second through-electrodes 220 or the plurality of first through-electrodes 120 that are located below the third wiring structure 330.

For example, the plurality of third wiring patterns 332 and/or the plurality of third wiring vias 334 of the third wiring structure 330 included in the third semiconductor chip 300 may be respectively and electrically connected to the plurality of second through-electrodes 220 included in the lowermost second semiconductor chip 200L, located below the third semiconductor chip 300, through some of the plurality of bonding pads 420 that are the plurality of third bonding pads.

The plurality of bonding pads 420 may be surrounded by a plurality of chip bonding insulating layers 400 between the first semiconductor chip 100 and the lowermost second semiconductor chip 200L, between the plurality of second semiconductor chips 200 and the third semiconductor chip 300, and between the plurality of second semiconductor chips 200. The plurality of bonding pads 420 may pass through the plurality of chip bonding insulating layers 400. Each of the plurality of chip bonding insulating layers 400 may be between the first semiconductor chip 100, the plurality of second semiconductor chips 200, and the third semiconductor chip 300.

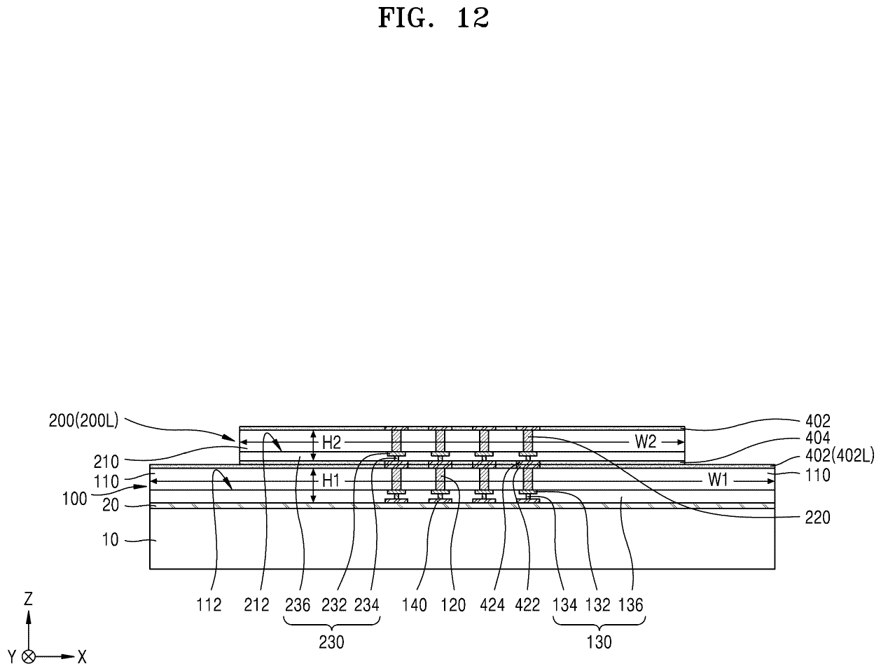

Each of the plurality of bonding pads 420 may be formed by forming conductive material layers such as, for example, a plurality of upper surface chip connection pads 422 and a plurality of lower surface chip connection pads 424 illustrated in FIG. 12, on facing surfaces of two adjacent chips among the first semiconductor chip 100, the plurality of second semiconductor chips 200, and the third semiconductor chip 300, and then applying heat to the conductive material layers that face each other to be expanded and come into contact with each other, and diffusion-bonding the conductive material layers to form one body through diffusion of included metal atoms.

The chip bonding insulating layer 400 may be formed by forming insulating material layers such as, for example, an upper surface chip bonding insulating material layer 402 and a lower surface chip bonding insulating material layer 404 illustrated in FIG. 12, on facing surfaces of two adjacent chips among the first semiconductor chip 100, the plurality of second semiconductor chips 200, and the third semiconductor chip 300, and then, while the plurality of bonding pads 420 are formed, by applying heat to the insulating material layers facing each other to be expanded and come into contact with each other, and diffusion-bonding the insulating material layers to form one body through diffusion of included atoms.

A vertical height of each of the plurality of chip bonding insulating layers 400 may be about 100 nanometers to about 1 micrometer.

Among the plurality of chip bonding insulating layers 400, a lowermost chip bonding insulating layer 400L between the first semiconductor chip 100 and the lowermost second semiconductor chip 200L may be formed by diffusion-bonding an insulating material layer covering an upper surface of the first semiconductor chip 100 and an insulating material layer covering a lower surface of the lowermost second semiconductor chip 200L such as, for example, a lowermost upper surface chip bonding insulating material layer 402L and a lower surface chip bonding insulating material layer 404 illustrated in FIG. 12.

The lowermost chip bonding insulating layer 400L may have a first recess 400R in a part of an outer side thereof such that a thickness of a portion of the lowermost chip bonding insulating layer 400L that overlaps with the lowermost second semiconductor chip 200L in the vertical direction is greater than a thickness of a portion of the lowermost chip bonding insulating layer 400L that does not overlap with the lowermost second semiconductor chip 200L in the vertical direction. The first recess 400R may be in a portion of the lowermost chip bonding insulating layer 400L which does not overlap with the lowermost second semiconductor chip 200L in the vertical direction. A central portion of the lowermost chip bonding insulating layer 400L (e.g., a portion of the lowermost chip bonding insulating layer 400L which overlaps with the lowermost second semiconductor chip 200L in the vertical direction) may protrude more than an edge portion of the lowermost chip bonding insulating layer 400L (e.g., a portion that does not overlap with the lowermost second semiconductor chip 200L in the vertical direction) in the vertical direction, and the lowermost chip bonding insulating layer 400L may have a flat lower surface.

The lowermost chip bonding insulating layer 400L may cover all portions of an upper surface of the first semiconductor chip 100 which do not overlap with the lowermost second semiconductor chip 200L in the vertical direction. A portion of the upper surface of the first semiconductor chip 100 which overlaps with the lowermost second semiconductor chip 200L in the vertical direction and a part of a lower surface of the lowermost second semiconductor chip 200L may be covered by a plurality of bonding pads 420, and the other portions of the upper surface of the first semiconductor chip 100 and the lower surface of the lowermost second semiconductor chip 200L may be covered by the lowermost chip bonding insulating layer 400L.

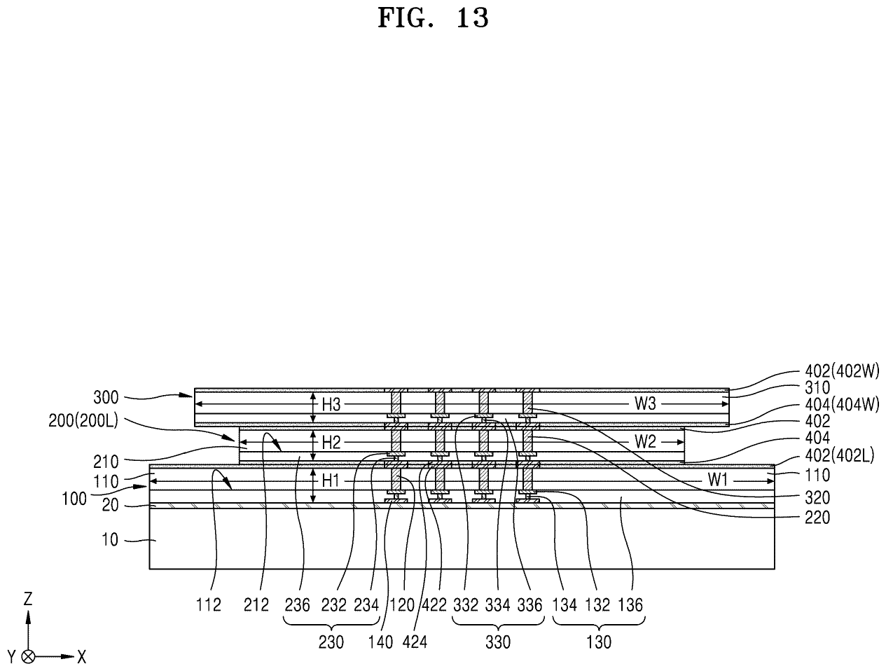

Among the plurality of chip bonding insulating layers 400, a wide chip bonding insulating layer 400W between the lowermost second semiconductor chip 200L and the third semiconductor chip 300 may be formed by diffusion-bonding an insulating material layer covering an upper surface of the lowermost second semiconductor chip 200L below the third semiconductor chip 300, and an insulating material layer covering a lower surface of the third semiconductor chip 300. For example, the insulating materials may be an upper surface chip bonding insulating material layer 402 and a lower surface chip bonding insulating material layer 404 illustrated in FIG. 13.

In addition, a wide chip bonding insulating layer 400W between the third semiconductor chip 300 and the second semiconductor chip 200, above the third semiconductor chip 300, may be formed by diffusion-bonding an insulating material layer covering an upper surface of the third semiconductor chip 300 and an insulating material layer covering a lower surface of the second semiconductor chip 200 above the third semiconductor chip 300.

Each wide chip bonding insulating layer 400W may have a second recess 400R_W in a part of an outer side of the wide chip bonding insulating layer 400W such that a thickness of a portion of the wide chip bonding insulating layer 400W which overlaps with the second semiconductor chip 200 in the vertical direction is greater than a thickness of a portion of the wide chip bonding insulating layer 400W which does not overlap with the second semiconductor chip 200 in the vertical direction. The second recess 400R_W may be in a portion of the wide chip bonding insulating layer 400W which does not overlap with the lowermost second semiconductor chip 200L in the vertical direction. A central portion of the wide chip bonding insulating layer 400W (e.g., a portion of the wide chip bonding insulating layer 400W that overlaps with the lowermost second semiconductor chip 200L in the vertical direction) may protrude more than an edge portion of the wide chip bonding insulating layer 400W (e.g., a portion of the wide chip bonding insulating layer 400W that does not overlap with the lowermost second semiconductor chip 200L in the vertical direction) in the vertical direction, and the wide chip bonding insulating layer 400W may have a flat lower surface.

A support dummy substrate 500 may be stacked over the uppermost second semiconductor chip 200H. The support dummy substrate 500 may include, for example, a semiconductor material, such as silicon (Si). In some embodiments, the support dummy substrate 500 may be formed of only the semiconductor material. For example, the support dummy substrate 500 may be a portion of a bare wafer.

The support dummy substrate 500 may have a fourth horizontal width W4 and a fourth vertical height H4. In some embodiments, the fourth horizontal width W4 may be less than the first horizontal width W1 and the third horizontal width W3. In some embodiments, the fourth vertical height H3 may be greater than the first vertical height H1, the second vertical height H2, and the third vertical height H3. For example, the fourth vertical height H4 may be about 100 mm to about 500 mm.

A support bonding insulating layer 450 may be between the uppermost second semiconductor chip 200H and the support dummy substrate 500. The support bonding insulating layer 450 may be formed by forming insulating material layers respectively on an upper surface of the uppermost second semiconductor chip 200H and a lower surface of the support dummy substrate 500 that face each other, and then by applying heat to the insulating material layers facing each other to be expanded and come into contact with each other, and by diffusion-bonding the insulating material layers to form one body through diffusion of included atoms.

The chip bonding insulating layer 400 and the support bonding insulating layer 350 may each include any one from among SiO, SiN, SiCN, SiCO, and a polymer material. The polymer material may be benzocyclobutene (BCB), polyimide (PI), polybenzoxazole (PBO), silicone, acrylate, or epoxy. For example, the chip bonding insulating layer 400 and the support bonding insulating layer 350 may each include silicon oxide. In some embodiments, the chip bonding insulating layer 400 and the support bonding insulating layer 350 may include the same material as each other. The chip bonding insulating layer 400 and the support bonding insulating layer 350 may each have a thickness of, for example, about 100 nm to about 1 mm.

The semiconductor package 10a may further include a package molding layer 800 formed on the first semiconductor chip 100 to cover a part of an upper surface of the first semiconductor chip 100 and a side support layer 600a, and surrounding sides of the plurality of second semiconductor chips 200, the third semiconductor chip 300, and the support dummy substrate 500. The package molding layer 800 may include, for example, epoxy mold compound (EMC). In some embodiments, the package molding layer 800 may not cover an upper surface of the support dummy substrate 500. In some other embodiments, the package molding layer 800 may cover the upper surface of the support dummy substrate 500.

In some embodiments, the semiconductor package 10a may further include a redistribution structure 700 on a lower surface of the first semiconductor chip 100. The redistribution structure 700 may include a plurality of package redistribution line patterns 720, a plurality of package redistribution vias 740, and a package redistribution insulating layer 760. In some embodiments, a plurality of package redistribution insulating layers 760 may be stacked. The package redistribution insulating layer 760 may include, for example, photo imageable dielectric (PID) or photosensitive polyimide (PSPI). The plurality of package redistribution line patterns 720 and the plurality of package redistribution vias 740 may each include metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof, but is not limited thereto. In some embodiments, the plurality of package redistribution line patterns 720 and the plurality of package redistribution vias 740 may be formed by stacking metal or metal alloy on a seed layer including titanium, titanium nitride, or titanium tungsten.

The plurality of package redistribution line patterns 720 may be on at least one from among upper and lower surfaces of the package redistribution insulating layer 760. Each of the plurality of package redistribution vias 740 may pass through the package redistribution insulating layer 760 to be connected to a part of each of the plurality of package redistribution line patterns 720. In some embodiments, at least some of the plurality of package redistribution line patterns 720 may be integrally formed with at least some of the plurality of package redistribution vias 740. For example, the package redistribution line pattern 720 may be integrated with the package redistribution via 740 in contact with an upper surface of the package redistribution line pattern 720. The package redistribution insulating layer 760 may surround the plurality of package redistribution line patterns 720 and the plurality of package redistribution vias 740.

The plurality of package redistribution line patterns 720 and the plurality of package redistribution vias 740 may be respectively and electrically connected to the plurality of chip pads 140. In some embodiments, at least some of the plurality of package redistribution vias 740 may be in contact with the plurality of chip pads 140. For example, when the redistribution structure 700 includes the plurality of package redistribution insulating layers 760 that are stacked, the plurality of package redistribution vias 740 passing through the uppermost one of the package redistribution insulating layers 760 may be respectively and electrically connected to the plurality of chip pads 140.

In some embodiments, the plurality of package redistribution vias 740 may each have a tapered shape extending while a horizontal width thereof narrows from the bottom to the top. That is, the plurality of package redistribution vias 740 may increase in horizontal width while moving away from the first semiconductor chip 100.

Among the plurality of package redistribution line patterns 720, the package redistribution line patterns 720 on a lower surface of the redistribution structure 700 may be referred to as package pads 650. A plurality of package connection terminals 900 may be respectively attached to the package pads 650. For example, the plurality of package connection terminals 900 may each be a solder ball or a bump.

In some embodiments, the semiconductor package 10a may not include the redistribution structure 700. For example, the plurality of package connection terminals 900 may be respectively attached to the plurality of chip pads 140.

A horizontal width and horizontal area of the redistribution structure 700 may be equal to a horizontal width and horizontal area of the first semiconductor chip 100. The redistribution structure 700 and the first semiconductor chip 100 may overlap with each other in a vertical direction (the Z direction).

For example, the horizontal width and horizontal area of the redistribution structure 700, the horizontal width and horizontal area of the first semiconductor chip 100, and a horizontal width and horizontal area of the package molding layer 800 may be substantially equal to each other. Side surfaces of the redistribution structure 700, the first semiconductor chip 100, and the package molding layer 800 may be aligned in the vertical direction and may form a same plane (e.g., may be coplanar with each other).

The semiconductor package 10a according to an embodiment of the present disclosure may include the first semiconductor chip 100, the plurality of second semiconductor chips 200, and the third semiconductor chip 300 which are stacked and bonded to each other through hybrid bonding by which the plurality of bonding pads 420 are diffusion-bonded to the plurality of chip bonding insulating layers 400. Because the first semiconductor chip 100, the plurality of second semiconductor chips 200, and the third semiconductor chip 300 have thicknesses (vertical heights) that are substantially equal to each other and relatively thin, flexible bending may occur during the hybrid bonding and, accordingly, bonding defects may be prevented from being generated between the first semiconductor chip 100, the plurality of second semiconductor chips 200, and the third semiconductor chip 300. Also, stress may be prevented from being concentrated on the first semiconductor chip 100, the plurality of second semiconductor chips 200, and the third semiconductor chip 300, which are bonded to each other, during a subsequent thermal process.

According to one embodiment, the semiconductor package 10a may include the side support layer 600a between the first semiconductor chip 100 and the third semiconductor chip 300. The side support layer 600a may surround square edges of the third semiconductor chip 300 from a horizontal perspective. The third semiconductor chip 300 may protrude further in a lateral direction (the X direction and/or Y direction) compared to the plurality of second semiconductor chips 200 and, accordingly, a groove may be formed between the first semiconductor chip 100 and the third semiconductor chip 300. In this case, the side support layer 600a may fill (e.g., seal) the groove.

In a comparative embodiment, when the plurality of second semiconductor chips 200 are stacked at a high level, there may be delamination between the first semiconductor chip 100 and the lowermost second semiconductor chip 200L due to warpage. For example, in order to perform hybrid bonding between the plurality of bonding pads 420 and the plurality of chip bonding insulating layers 400, a thermal process is performed in a high temperature environment, and by the thermal process, the first semiconductor chip 100 and the lowermost second semiconductor chip 200L may be bent in the comparative embodiment. When the first semiconductor chip 100 and the lowermost second semiconductor chip 200L are bent in opposite directions, or when there is a difference in the degree of bending, the first semiconductor chip 100 may be detached from the lowermost second semiconductor chip 200L in the comparative embodiment. However, according to embodiments of the present disclosure, the side support layer 600a between the first semiconductor chip 100 and the third semiconductor chip 300 may fix the first semiconductor chip 100 to the lowermost second semiconductor chip 200L despite the warpage such that the first semiconductor chip 100 and the lowermost second semiconductor chip 200L are not separated from each other.

According to one embodiment, a side of the third semiconductor chip 300 protrudes in a lateral direction (the X direction and/or Y direction) more than a side of the lowermost second semiconductor chip 200L and, accordingly, the side support layer 600a attached to the third semiconductor chip 300 may more easily fix the third semiconductor chip 300 and the lowermost second semiconductor chip 200L to the first semiconductor chip 100.

Also, a side surface of the side support layer 600a may have a concave shape due to surface tension. For example, the side support layer 600a may include epoxy resin or a non-conductive film (NCF) but is not limited thereto.

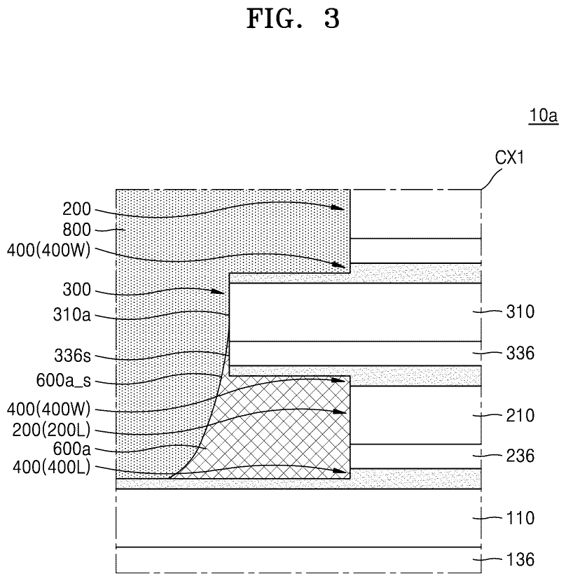

FIG. 3 is an enlarged view of a region CX1 of FIG. 2.

The semiconductor package 10a may include the side support layer 600a that seals a space between the first semiconductor chip 100 and the third semiconductor chip 300. The side support layer 600a may cover a part of a side surface 600a_s of the third semiconductor chip 300. However, the side support layer 600a does not cover the entire side surface 600a_s of the third semiconductor chip 300. The side support layer 600a may completely fill a space between the first semiconductor chip 100 and a region of the third semiconductor chip 300 which does not overlap with the plurality of second semiconductor chips 200. In this case, the side support layer 600a may cover a side surface of the lowermost second semiconductor chip 200L. Also, the side support layer 600a may cover a side surface of a region of the lowermost chip bonding insulating layer 400L that overlaps with the lowermost second semiconductor chip 200L.

The side support layer 600a may cover a side surface of the wide chip bonding insulating layer 400W on a lower surface of the third semiconductor chip 300. Also, the side support layer 600a may cover a lower surface of a region of the wide chip bonding insulating layer 400W which does not overlap with the plurality of second semiconductor chips 200.

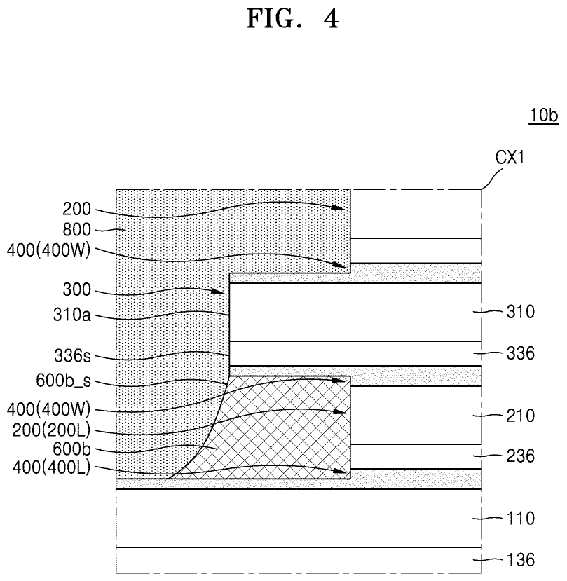

FIGS. 4, 5, and 6 are enlarged views of semiconductor packages 10b, 10c, and 10d according to embodiments and are enlarged views corresponding to FIG. 3.

The semiconductor packages 10b, 10c, and 10d illustrated in FIGS. 4, 5, and 6 are approximately identical or similar to the semiconductor package 10a illustrated in FIG. 3, except that side support layers 600b, 600c, and 600d are different from each other. Accordingly, repeated descriptions of components which are previously made with reference to FIGS. 2 and 3 may be omitted or simplified below.

Referring to FIG. 4, the semiconductor package 10b may include a side support layer 600b that seals a space between the first semiconductor chip 100 and the third semiconductor chip 300.

Unlike the side support layer 600a illustrated in FIG. 3, the side support layer 600b illustrated in FIG. 4 does not cover a side surface of the third semiconductor chip 300. Also, the side support layer 600b does not cover a side surface of the wide chip bonding insulating layer 400W on a lower surface of the third semiconductor chip 300. In this case, a side surface of the side support layer 600b may extend from the side surface of the third semiconductor chip 300 and the side surface of the wide chip bonding insulating layer 400W. A length of the side support layer 600b in a vertical direction (the Z direction) may be substantially equal to a length of a space, in the direction (Z direction), between the lowermost chip bonding insulating layer 400L and the wide chip bonding insulating layer 400W on the lower surface of the third semiconductor chip 300.

The side support layer 600b may completely fill a space between the first semiconductor chip 100 and a region of the third semiconductor chip 300 which does not overlap with the plurality of second semiconductor chips 200, as in the semiconductor package 10a illustrated in FIG. 3.

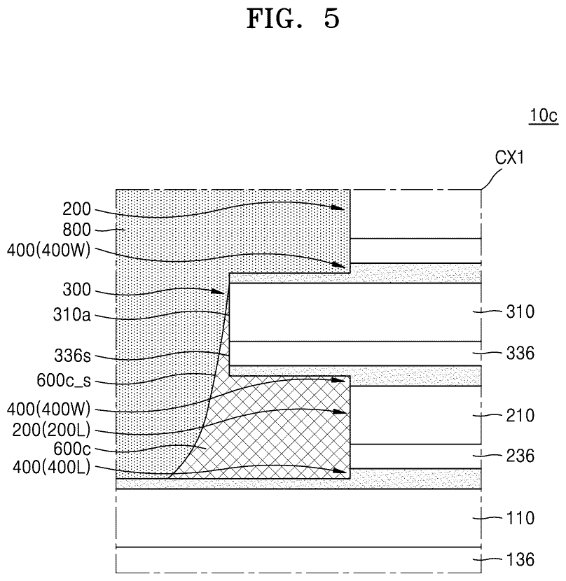

Referring to FIG. 5, the semiconductor package 10c may include the side support layer 600c that seals a space between the first semiconductor chip 100 and the third semiconductor chip 300.

Unlike the side support layer 600a illustrated in FIG. 3, the side support layer 600c illustrated in FIG. 5 may completely cover a side surface of the third semiconductor chip 300. Also, the side support layer 600c covers a side surface of the wide chip bonding insulating layer 400W on a lower surface of the third semiconductor chip 300. In this case, a side surface 600c_s of the side support layer 600c may extend from an upper surface of the wide chip bonding insulating layer 400W on an upper surface of the third semiconductor chip 300.

The side support layer 600c may completely fill a space between the first semiconductor chip 100 and a region of the third semiconductor chip 300 which does not overlap with the plurality of second semiconductor chips 200, as in the semiconductor package 10a illustrated in FIG. 3.

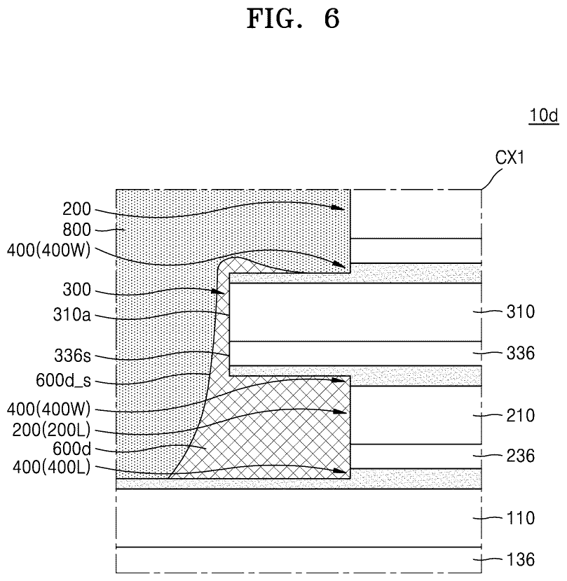

Referring to FIG. 6, the semiconductor package 10d may include the side support layer 600d that seals a space between the first semiconductor chip 100 and the third semiconductor chip 300.

Unlike the side support layer 600a illustrated in FIG. 3, the side support layer 600d illustrated in FIG. 6 may cover a side surface of the third semiconductor chip 300 and an upper surface of the wide chip bonding insulating layer 400W on the third semiconductor chip 300. Also, the side support layer 600d covers a side surface of the wide chip bonding insulating layer 400W on a lower surface of the third semiconductor chip 300. In this case, a side surface of the side support layer 600d may completely overlap with the first semiconductor chip 100 and the lowermost second semiconductor chip 200L in a lateral direction (the X direction and/or Y direction). The longest length of the side support layer 600d in a vertical direction (the Z direction) may be longer than a length, in the vertical direction (Z direction), from an upper surface of the lowermost chip bonding insulating layer 400L to an upper surface of the wide chip bonding insulating layer 400W on an upper surface of the third semiconductor chip 300.

The side support layer 600d may completely fill a space between the first semiconductor chip 100 and a region of the third semiconductor chip 300 which does not overlap with the plurality of second semiconductor chips 200, as in the semiconductor package 20a illustrated in FIG. 3.

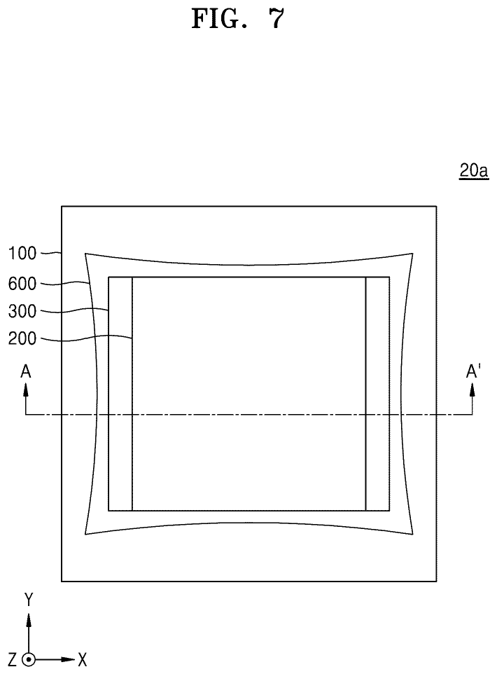

FIG. 7 is a plan view of a semiconductor package 20a according to an embodiment.

The semiconductor package 20a illustrated in FIG. 7 is almost identical or similar to the semiconductor package 10a illustrated in FIGS. 1 and 2, except a horizontal width of the third semiconductor chip 300 in a second horizontal direction (the Y direction). Accordingly, repeated descriptions of components which are previously made with reference to FIGS. 2 and 3 may be omitted or simplified below.

A first semiconductor chip 100 of the semiconductor package 20a illustrated in FIG. 7 may have a greater planar area than a planar area of each of a second semiconductor chip 200 and a third semiconductor chip 300 in a plan view. In this case, the third semiconductor chip 300 may have a horizontal length in a first horizontal direction (the X direction) which is greater than a horizontal length of the second semiconductor chip 200. However, in the semiconductor package 20a illustrated in FIG. 7, a length of the third semiconductor chip 300 in the second horizontal direction (the Y direction) may be substantially equal to a length of the second semiconductor chip 200 in the second horizontal direction (the Y direction). Also, an edge of the second semiconductor chip 200 in the second horizontal direction (the Y direction) may overlap with an edge of the third semiconductor chip 300 in the second horizontal direction (the Y direction).

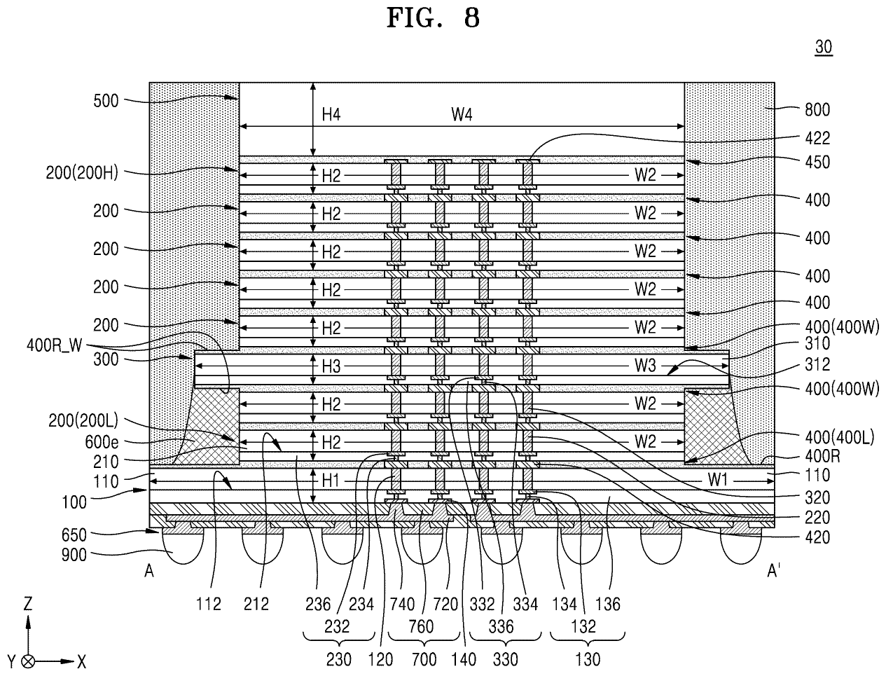

FIGS. 8, 9, 10, and 11 are cross-sectional views of semiconductor packages 30, 40, 50, and 60 according to embodiments.

Hereinafter, differences from the semiconductor package 10a illustrated in FIGS. 1 and 2 are mainly described, and previous description of components of FIGS. 1 and 2 may not be repeated.

Referring to FIG. 8, the semiconductor package 30 may include a side support layer 600e that seals a space between a first semiconductor chip 100 and a third semiconductor chip 300.

Unlike the semiconductor package 10a illustrated in FIG. 2, the semiconductor package 30 illustrated in FIG. 8 may include two second semiconductor chips 200 between the third semiconductor chip 300 and the first semiconductor chip 100. In this case, the side support layer 600e may cover at least a part of a side surface of the third semiconductor chip 300. Also, the side support layer 600e may cover side surfaces of the two second semiconductor chips 200 between the third semiconductor chip 300 and the first semiconductor chip 100.

As in the semiconductor package 10a illustrated in FIG. 2, the side support layer 600e may completely fill a space between the first semiconductor chip 100 and a region of the third semiconductor chip 300 which does not overlap with a plurality of second semiconductor chips 200.

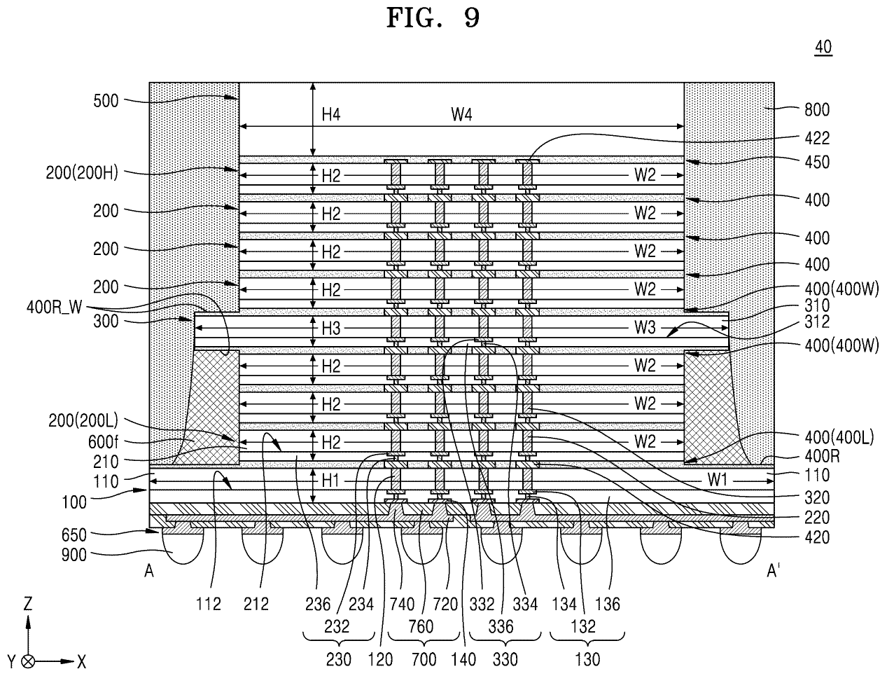

Referring to FIG. 9, the semiconductor package 40 may include the side support layer 600f that seals a space between the first semiconductor chip 100 and the third semiconductor chip 300.

Unlike the semiconductor package 10a illustrated in FIG. 2, the semiconductor package 40 illustrated in FIG. 9 may include three second semiconductor chips 200 between the third semiconductor chip 300 and the first semiconductor chip 100. In this case, the side support layer 600e may cover at least a part of a side surface of the third semiconductor chip 300. Also, the side support layer 600e may cover side surfaces of the three second semiconductor chips 200 between the third semiconductor chip 300 and the first semiconductor chip 100.

As in the semiconductor package 10a illustrated in FIG. 2, the side support layer 600e may completely fill a space between the first semiconductor chip 100 and a region of the third semiconductor chip 300 which does not overlap with the plurality of second semiconductor chips 200.

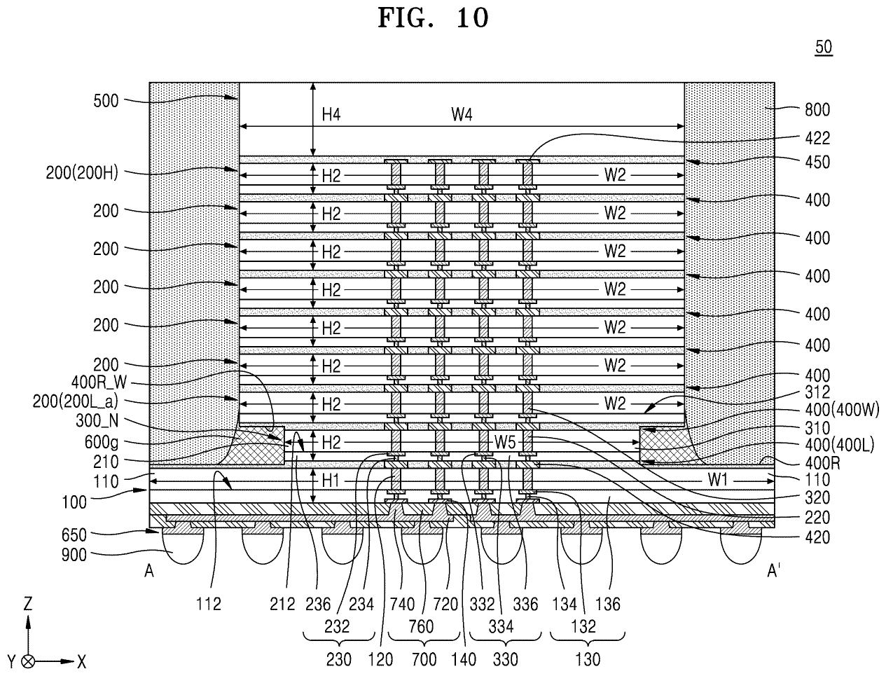

Referring to FIG. 10, the semiconductor package 50 may include a side support layer 600g that seals a space between the first semiconductor chip 100 and a lowermost second semiconductor chip 200L.

Unlike the third semiconductor chip 300 illustrated in FIG. 2, the third semiconductor chip 300 of the semiconductor package 50 illustrated in FIG. 10 has a fifth horizontal width W5 in a lateral direction (the X direction and/or Y direction) that is less than second horizontal widths W2 of the plurality of second semiconductor chips 200 in a lateral direction (the X direction and/or Y direction).

Also, the third semiconductor chip 300 may be between the first semiconductor chip 100 and the lowermost second semiconductor chip 200L_a. Accordingly, a groove may be formed between the lowermost second semiconductor chip 200L_a and the first semiconductor chip 100, and the side support layer 600g may be configured to seal the groove.

The side support layer 600g completely covers a side surface of the third semiconductor chip 300 and may cover at least a part of a side surface of the lowermost second semiconductor chip 200L_a. The side support layer 600g may cover a side surface of the wide chip bonding insulating layer 400W on a lower surface of the lowermost second semiconductor chip 200L_a.

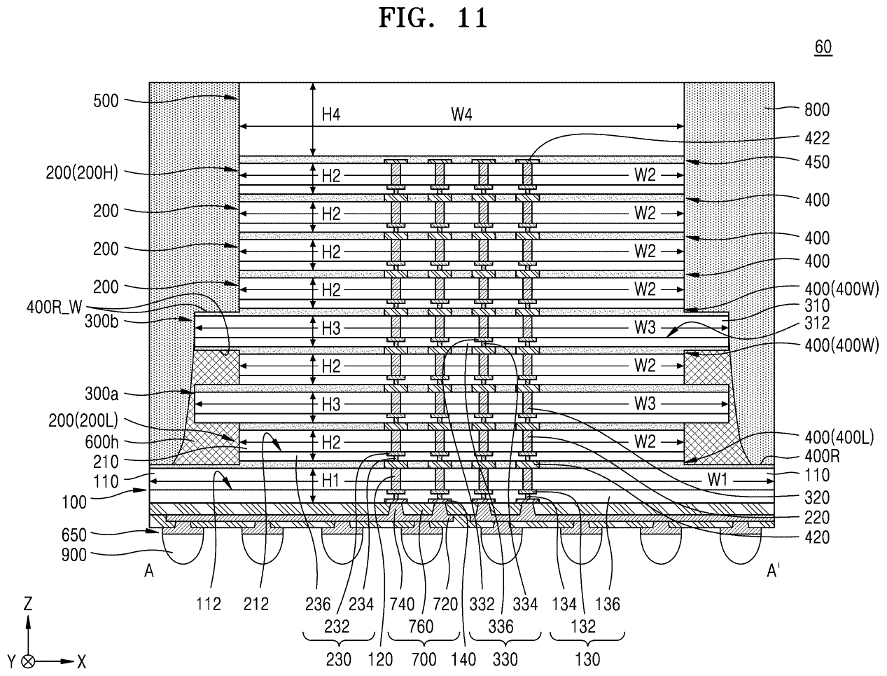

Referring to FIG. 11, the semiconductor package 60 may include a plurality of third semiconductor chips 300.

The plurality of third semiconductor chips 300 may include a lower third semiconductor chip 300a between the lowermost second semiconductor chip 200L and the second semiconductor chip 200 thereon, and an upper third semiconductor chip 300b above the lower third semiconductor chip 300a and separated in a vertical direction (the Z direction) from the lower third semiconductor chip 300a with the second semiconductor chip 200 therebetween.

According to one embodiment, the semiconductor package 60 may include a side support layer 600h that seals a space between the first semiconductor chip 100 and the lower third semiconductor chip 300a. Also, the side support layer 600h may seal a space between the upper third semiconductor chip 300b and the lower third semiconductor chip 300a.

Each of the upper third semiconductor chip 300b and the lower third semiconductor chip 300a may have substantially the same shape as the third semiconductor chip 300 illustrated in FIG. 2.

The side support layer 600h may surround square edges of the third semiconductor chip 300 from a horizontal perspective. The lower third semiconductor chip 300a and the upper third semiconductor chip 300b may protrude in a lateral direction (the X direction and/or Y direction) more than the second semiconductor chip 200 and, accordingly, grooves may be respectively formed between the upper third semiconductor chip 300b and the lower third semiconductor chip 300a, and between the lower third semiconductor chip 300a and the first semiconductor chip 100. In this case, the side support layer 600h may seal the grooves.

Materials forming the side support layers 600e, 600f, 600g, and 600h respectively illustrated in FIGS. 8 to 11 are substantially the same as a material forming the side support layer 600a illustrated in FIG. 2, and accordingly, repeated description thereof may be omitted.

FIGS. 12 to 20 are cross-sectional views sequentially illustrating manufacturing processes of the semiconductor package 10a according to an embodiment.

Referring to FIG. 12, a plurality of upper surface chip connection pads 422 and the upper surface chip bonding insulating material layer 402 are formed on an upper surface of the first semiconductor chip 100. The plurality of upper surface chip connection pads 422 may be on an upper surface (e.g., an inactive surface) of the first semiconductor chip 100. The plurality of upper surface chip connection pads 422 may be on the upper surface of the first semiconductor chip 100 to be respectively connected to the plurality of first through-electrodes 120. The upper surface chip bonding insulating material layer 402 may surround side surfaces of the plurality of upper surface chip connection pads 422 on the upper surface (e.g., the inactive surface) of the first semiconductor chip 100. The upper surface chip bonding insulating material layer 402 may cover the upper surface of the first semiconductor chip 100 and side surfaces of the plurality of upper surface chip connection pads 422, but does not cover upper surfaces of the plurality of upper surface chip connection pads 422 such that the upper surfaces of the plurality of upper surface chip connection pads 422 are exposed.

The first semiconductor chip 100, with the plurality of upper surface chip connection pads 422 and the upper surface chip bonding insulating material layer 402 formed on the upper surface of the first semiconductor chip 100, is attached onto the first support substrate 10. After a first release film 20 is attached to the upper surface of the first support substrate 10, the first semiconductor chip 100 may be attached onto the first release film 20. The first semiconductor chip 100 may be attached onto the first release film 20 such that the first wiring structure 130 faces the first support substrate 10.

A plurality of upper surface chip connection pads 422 and an upper surface chip bonding insulating material layer 402 are also formed on an upper surface of the second semiconductor chip 200. The plurality of upper surface chip connection pads 422 may be on the upper surface (e.g., an inactive surface) of the second semiconductor chip 200. The plurality of upper surface chip connection pads 422 may be on the upper surface of the second semiconductor chip 200 to be connected to the plurality of second through-electrodes 220. The upper surface chip bonding insulating material layer 402 may be formed on the upper surface (e.g., an inactive surface) of the second semiconductor chip 200, to surround side surfaces of the plurality of upper surface chip connection pads 422. The upper surface chip bonding insulating material layer 402 may cover the upper surface of the second semiconductor chip 200 and the side surfaces of the plurality of upper surface chip connection pads 422 but may expose upper surfaces of the plurality of upper surface chip connection pads 422 without covering the upper surfaces of the plurality of upper surface chip connection pads 422.

The plurality of lower surface chip connection pads 424 and the lower surface chip bonding insulating material layer 404 are formed on a lower surface of the second semiconductor chip 200. The plurality of lower surface chip connection pads 424 may be on a lower surface of the second semiconductor chip 200, that is, a lower surface of the second wiring structure 230. The plurality of lower surface chip connection pads 424 may be on the lower surface of the second semiconductor chip 200 to be respectively connected to the plurality of second wiring pattern 232 and/or the plurality of second wiring vias 234. The lower surface chip bonding insulating material layer 404 may be formed on the lower surface of the second semiconductor chip 200 to surround side surfaces of the plurality of lower surface chip connection pads 424. The lower surface chip bonding insulating material layer 404 may cover the lower surface of the second semiconductor chip 200 and side surfaces of the plurality of lower surface chip connection pads 424 but may expose lower surfaces of the plurality of lower surface chip connection pads 424 without covering the lower surfaces of the plurality of lower surface chip connection pads 424.

Among the upper surface chip bonding insulating material layers 402 formed on the upper surfaces of the first semiconductor chip 100 and the plurality of second semiconductor chips 200, the upper surface chip bonding insulating material layer 402 formed on the upper surface of the first semiconductor chip 100 may be referred to as a lowermost upper surface chip bonding insulating material layer 402L.

The second semiconductor chip 200 may be on the first semiconductor chip 100. The second semiconductor chip 200 may be the lowermost second semiconductor chip 200L illustrated in FIG. 1. The lowermost second semiconductor chip 200L may be on the first semiconductor chip 100 such that the second wiring structure 230 faces the first semiconductor chip 100. The lowermost second semiconductor chip 200L may be on the first semiconductor chip 100 such that the plurality of lower surface chip connection pads 424 formed on a lower surface of the lowermost second semiconductor chip 200L respectively correspond to the plurality of lower surface chip connection pads 424 formed on an upper surface of the first semiconductor chip 100. For example, the plurality of upper surface chip connection pads 422 and the plurality of lower surface chip connection pads 424 may each include a material including Cu.

Referring to FIG. 13, the plurality of upper surface chip connection pads 422 and the wide upper surface chip bonding insulating material layer 402W may also be formed on an upper surface of the third semiconductor chip 300. The wide upper surface chip bonding insulating material layer 402W may have a greater horizontal width in a lateral direction (the X direction and/or Y direction) than horizontal widths of the other upper surface chip bonding insulating material layers 402. The plurality of upper surface chip connection pads 422 may be on the upper surface (e.g., an inactive surface) of the third semiconductor chip 300. The plurality of upper surface chip connection pads 422 may be on the upper surface of the third semiconductor chip 300 to be respectively connected to the plurality of third through-electrodes 320. The wide upper surface chip bonding insulating material layer 402W may be on the upper surface (e.g., an inactive surface) of the third semiconductor chip 300 to surround the side surfaces of the plurality of upper surface chip connection pads 422. The wide upper surface chip bonding insulating material layer 402W may cover the upper surface of the third semiconductor chip 300 and side surfaces of the plurality of upper surface chip connection pads 422 but may expose upper surfaces of the plurality of upper surface chip connection pads 422 without covering the upper surfaces of the plurality of upper surface chip connection pads 422.

The plurality of lower surface chip connection pads 424 and the wide lower surface chip bonding insulating material layer 404W may be formed on a lower surface of the third semiconductor chip 300. The wide lower surface chip bonding insulating material layer 404W may have a greater horizontal width in a lateral direction (the X direction and/or Y direction) than a horizontal width of the lower surface chip bonding insulating material layer 404. The plurality of lower surface chip connection pads 424 may be on the lower surface of the third semiconductor chip 300, that is, a lower surface of the third wiring structure 330. The plurality of lower surface chip connection pads 424 may be on the lower surface of the third semiconductor chip 300 to be respectively connected to the plurality of third wiring patterns 332 and/or the plurality of third wiring vias 334. The wide lower surface chip bonding insulating material layer 404W may be on the lower surface of the third semiconductor chip 300 to surround side surfaces of the plurality of lower surface chip connection pads 424. The wide lower surface chip bonding insulating material layer 404W may cover the lower surface of the third semiconductor chip 300 and the side surfaces of the plurality of lower surface chip connection pads 424 but expose lower surface of the plurality of lower surface chip connection pads 424 without covering lower surface of the plurality of lower surface chip connection pads 424.

The third semiconductor chip 300 may be on the second semiconductor chip 200. The second semiconductor chip 200 may be the lowermost second semiconductor chip 200L illustrated in FIG. 2. The third semiconductor chip 300 may be on the lowermost second semiconductor chip 200L such that the third wiring structure 330 faces the lowermost second semiconductor chip 200L. The third semiconductor chip 300 may be on the lowermost second semiconductor chip 200L such that the plurality of lower surface chip connection pads 424 formed on the lower surface of the third semiconductor chip 300 respectively correspond to the plurality of upper surface chip connection pads 422 formed on the upper surface of the lowermost second semiconductor chip 200L.

The plurality of second semiconductor chips 200 may each have a second horizontal width W2, and the third semiconductor chip 300 may have a third horizontal width W3 that is greater than the second horizontal width W2. In some embodiments, the third horizontal width W3 may be greater than the second horizontal width W2 by several micrometers to several hundred micrometers.

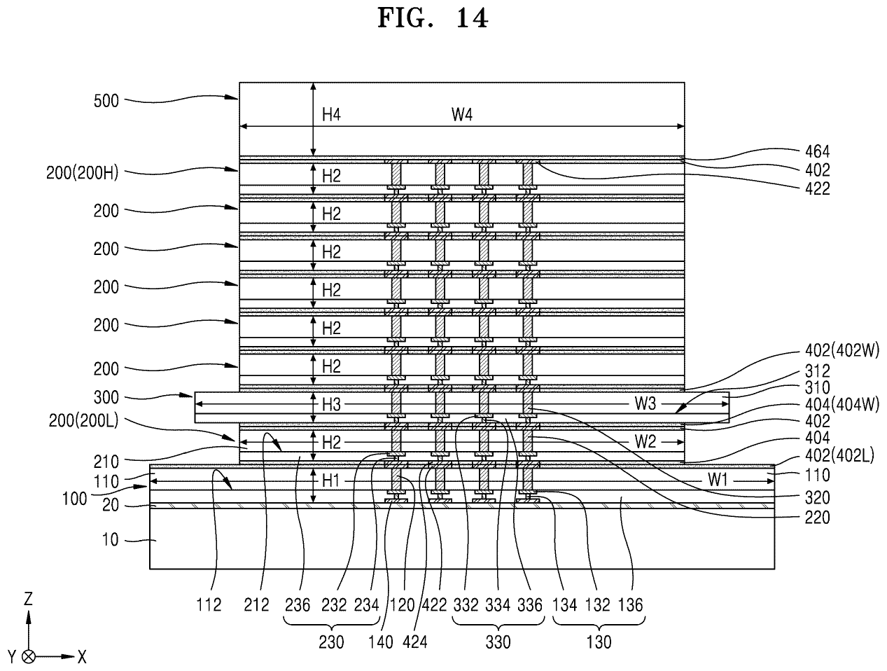

Referring to FIG. 14, the plurality of second semiconductor chips 200 may be sequentially arranged on the third semiconductor chip 300. The plurality of lower surface chip connection pads 424 and the lower surface chip bonding insulating material layer 404 may be formed on each of lower surfaces of the plurality of second semiconductor chips 200 sequentially arranged on the third semiconductor chip 300, and the plurality of upper surface chip connection pads 422 and the upper surface chip bonding insulating material layer 402 may be formed on each of upper surfaces of the plurality of second semiconductor chips 200.

Thereafter, the lower surface dummy bonding insulating material layer 464 may be formed on a lower surface of the support dummy substrate 500, and then the support dummy substrate 500 may be arranged on the uppermost second semiconductor chip 200H.

The plurality of second semiconductor chips 200 may each have a second horizontal width W2, and the support dummy substrate 500 may have a fourth horizontal width W3 that is equal to the second horizontal width W2. In some embodiments, the fourth horizontal width W4 may be less than the third horizontal width W3 of the third semiconductor chip by several micrometers to several hundred micrometers.

The support dummy substrate 500 may be on the uppermost second semiconductor chip 200H by using an edge of the uppermost second semiconductor chip 200H as an alignment key.

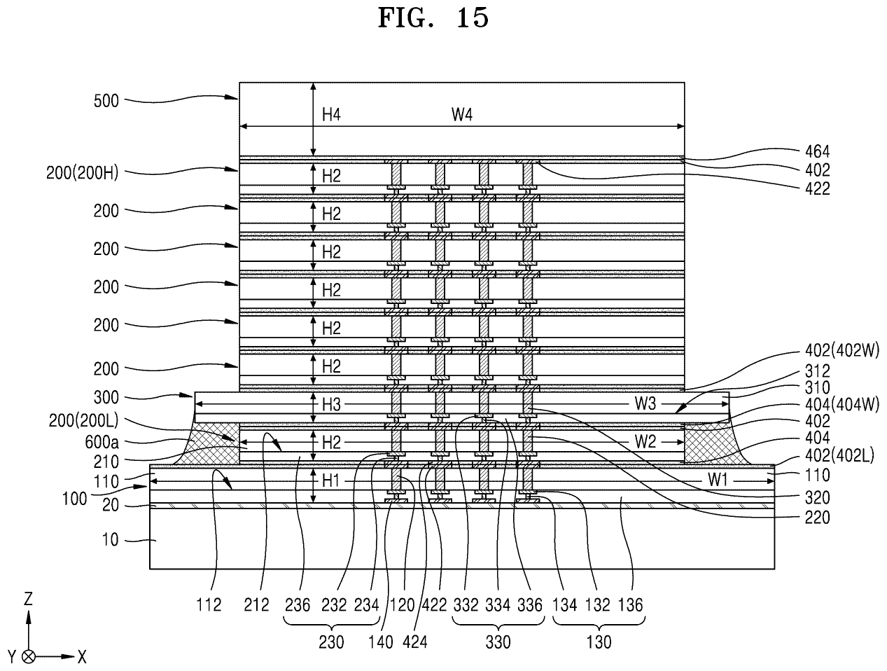

Referring to FIG. 15, the side support layer 600a may be formed to seal a groove between the first semiconductor chip 100 and the third semiconductor chip 300. According to one embodiment, while a dispenser nozzle is moved along an outer edge of the lowermost second semiconductor chip 200L, a non-conductive material may be dispensed in the groove between the first semiconductor chip 100 and the third semiconductor chip 300 through the dispenser nozzle. When a non-conductive film (NCF) is cured, the side support layer 600a may be formed. The side support layer 600a may be formed to completely surround a side surface of the lowermost second semiconductor chip 200L and to surround at least a part of a side surface of the third semiconductor chip 300. The side support layer 600a may include epoxy resin or an NCF but is not limited thereto.

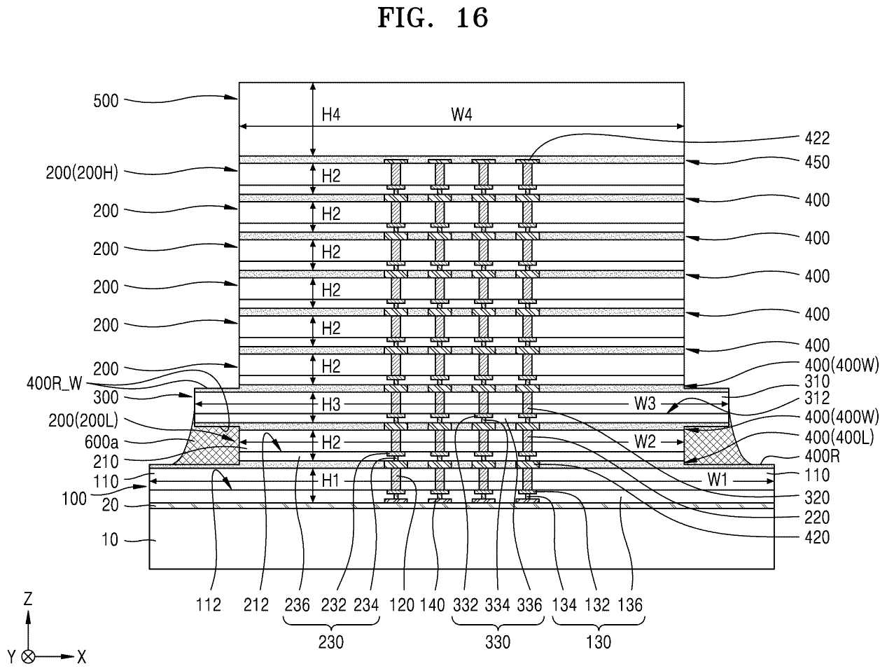

Referring to FIG. 16, heat and/or pressure may be applied to the first semiconductor chip 100, the plurality of second semiconductor chips 200, and the third semiconductor chip 300 to bond the plurality of upper surface chip connection pads 422 to the plurality of lower surface chip connection pads 424 and to bond the upper surface chip bonding insulating material layer 402 to the lower surface chip bonding insulating material layer 404. In some embodiments, the plurality of upper surface chip connection pads 422 and the plurality of lower surface chip connection pads 424 may be covalently bonded to each other, and the upper surface chip bonding insulating material layer 402 and the lower surface chip bonding insulating material layer 404 may be covalently bonded to each other.

Thereafter, the plurality of bonding pads 420 may be formed by bonding the plurality of upper surface chip connection pads 422 respectively to the plurality of lower surface chip connection pads 424, and the chip bonding insulating layer 400 may be formed by bonding the upper surface chip bonding insulating material layer 402 to the lower surface chip bonding insulating material layer 404. The chip bonding insulating layer 400 between the first semiconductor chip 100 and the lowermost second semiconductor chip 200L may be referred to as the lowermost chip bonding insulating layer 400L. The plurality of bonding pads 420 may be formed by applying heat to the plurality of upper surface chip connection pads 422 and the plurality of lower surface chip connection pads 424 corresponding to each other to be expanded and come into contact with each other, and then by diffusion-bonding the plurality of upper surface chip connection pads 422 and the plurality of lower surface chip connection pads 424 to form one body through diffusion of the included metal atoms.

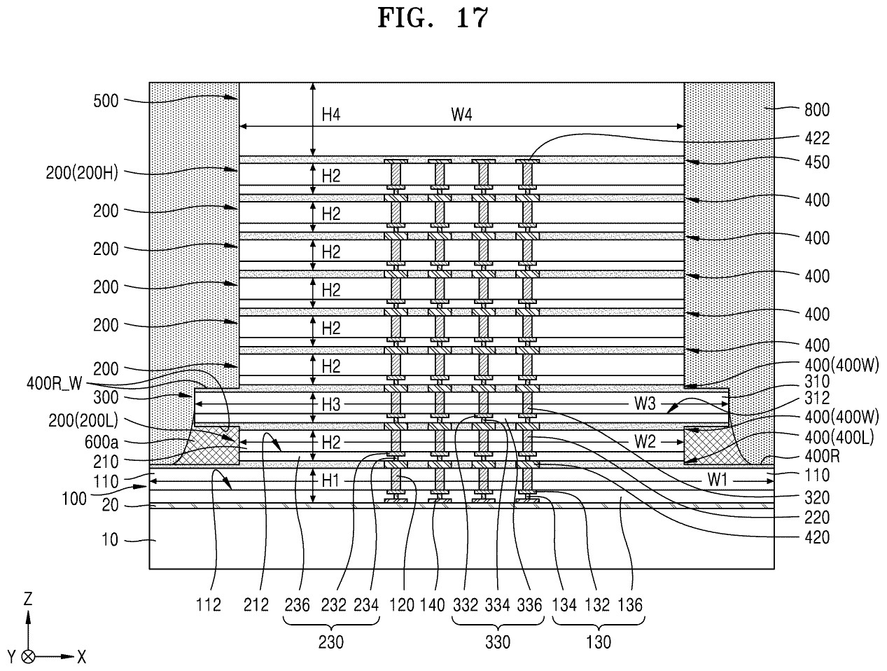

Referring to FIG. 17, the package molding layer 800 surrounding side surfaces of the first semiconductor chip 100, the plurality of second semiconductor chips 200, the third semiconductor chips 300, the support dummy substrate 500, and the side support layer 600a may be formed on the first semiconductor chip 100.

After the package molding layer 800 is formed, the first support substrate 10, to which the first release film 20 is attached, may be separated from the first semiconductor chip 100.

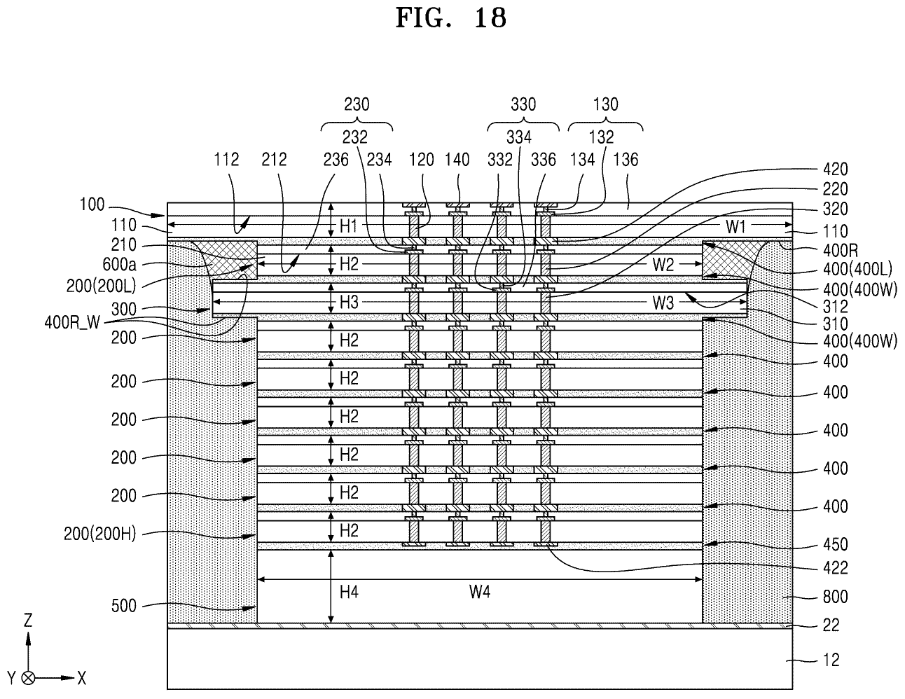

Referring to FIG. 18, a result of FIG. 17 is turned over and attached onto the second support substrate 12. The turned-over result of FIG. 17 may be attached onto a second release film 22 attached onto an upper surface of the second support substrate 12. The support dummy substrate 500 and the package molding layer 800 may be in contact with the second release film 22.

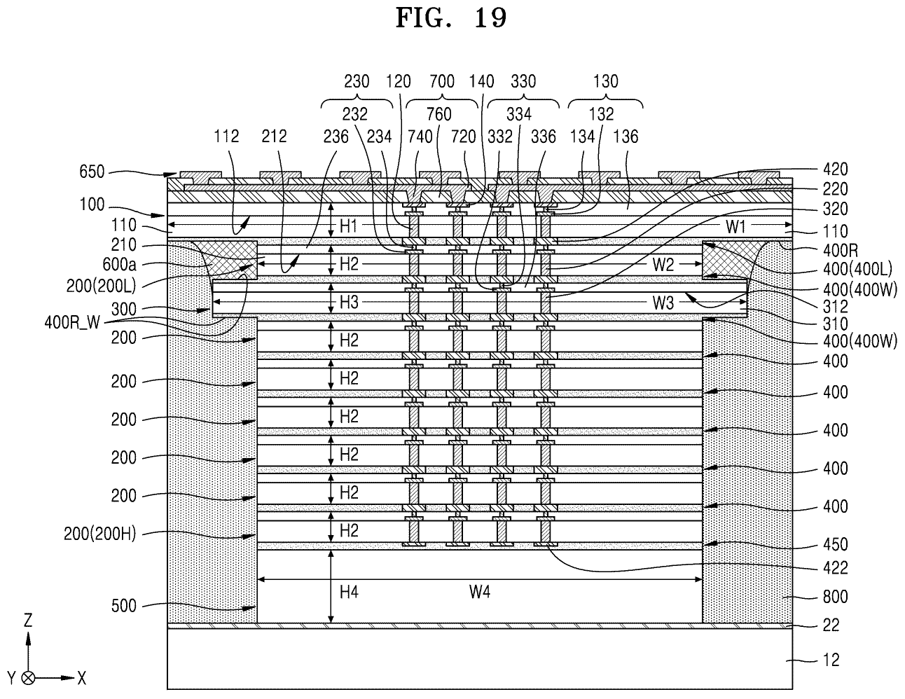

Referring to FIG. 19, the redistribution structure 700 may be formed on the first wiring structure 130 of the first semiconductor chip 100. The redistribution structure 700 may include the plurality of package redistribution line patterns 720, the plurality of package redistribution vias 740, and the package redistribution insulating layer 760. At least some of the plurality of package redistribution vias 740 or at least some of the plurality of package redistribution line patterns 720 may be respectively in contact with the plurality of chip pads 140. Among the plurality of package redistribution line patterns 720, the package redistribution line pattern 720 on an upper surface of the redistribution structure 700 may be referred to as a package pad 650.

In some embodiments, the plurality of package redistribution vias 740 may have a tapered shape that increases in horizontal width and extends from the bottom to the top of the package redistribution vias 740. That is, the plurality of package redistribution vias 740 may increase in horizontal width while moving away from the first semiconductor chip 100.

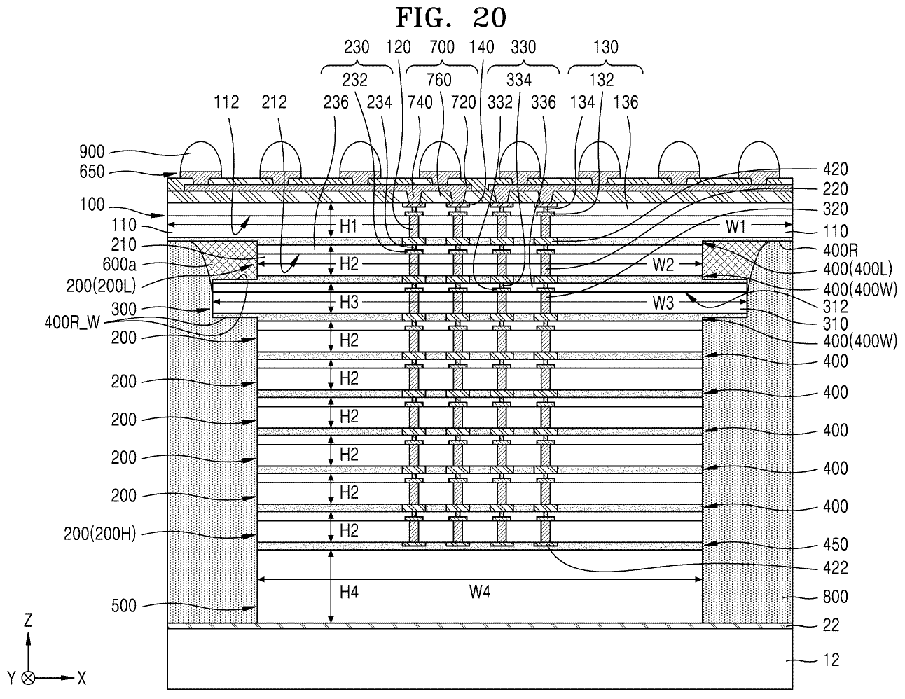

Referring to FIG. 20, the plurality of package connection terminals 900 may be attached to a plurality of package pads 650.

Thereafter, the second support substrate 12, to which the second release film 22 is attached, is separated from the support dummy substrate 500 and the package molding layer 800, and then a result thereof is turned over to form the semiconductor package 10a illustrated in FIG. 2.

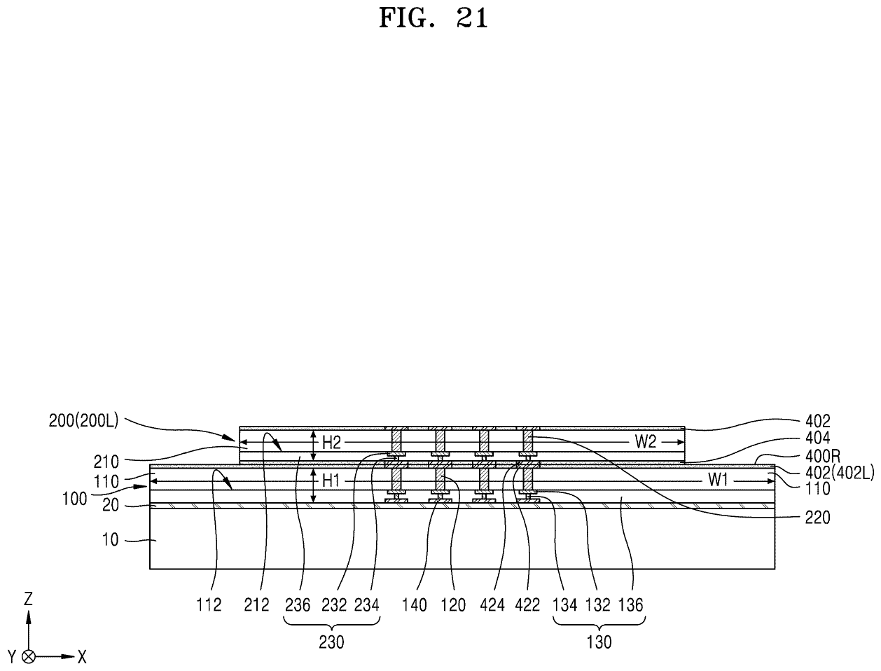

FIGS. 21 to 26 are cross-sectional views sequentially illustrating manufacturing processes of a semiconductor package according to an embodiment. The method of manufacturing a semiconductor package illustrated in FIGS. 21 to 26 differs from the method of manufacturing a semiconductor package illustrated in FIGS. 12 to 20 in a method of performing hybrid bonding of a chip bonding pad (e.g., the bonding pad 420).

The manufacturing process of the semiconductor package illustrated in FIG. 21 is similar to the manufacturing process of the semiconductor package illustrated in FIG. 12. Therefore, descriptions previously made with reference to FIG. 12 may be omitted below.

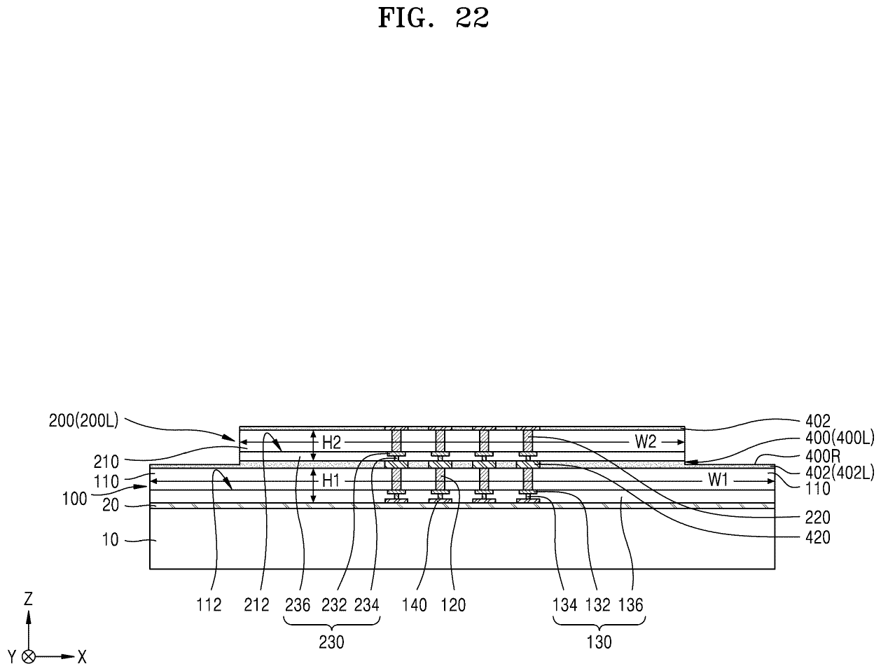

Referring to FIGS. 21 and 22, heat and/or pressure may be applied while the lowermost second semiconductor chip 200L is placed on the first semiconductor chip 100 to bond the plurality of upper surface chip connection pads 422 respectively to the plurality lower surface chip connection pads 424, and to bond the upper surface chip bonding insulating material layer 402 to the lower surface chip bonding insulating material layer 404. In some embodiments, the plurality of upper surface chip connection pads 422 and the plurality of lower surface chip connection pads 424, and the upper surface chip bonding insulating material layer 402 and the lower surface chip bonding insulating material layer 404 may be covalently bonded to each other. For example, heat at a first temperature may be applied while the second semiconductor chip 200 is placed on the first semiconductor chip 100.

Thereafter, heat at a second temperature higher than the first temperature may be applied to form the plurality of bonding pads 420 in which the plurality of upper surface chip connection pads 422 are respectively bonded to the plurality of lower surface chip connection pads 424, and to form the chip bonding insulating layer 400 in which the upper surface chip bonding insulating material layer 402 is bonded to the lower surface chip bonding insulating material layer 404. The chip bonding insulating layer 400 between the first semiconductor chip 100 and the lowermost second semiconductor chip 200L may be referred to as the lowermost chip bonding insulating layer 400L. The plurality of bonding pads 420 may be formed by applying heat to the plurality of upper surface chip connection pads 422 and the plurality of lower surface chip connection pads 424 corresponding to each other to be expanded and come into contact with each other, and then by diffusion-bonding the plurality of upper surface chip connection pads 422 and the plurality of lower surface chip connection pads 424 to form one body through diffusion of the included metal atoms.

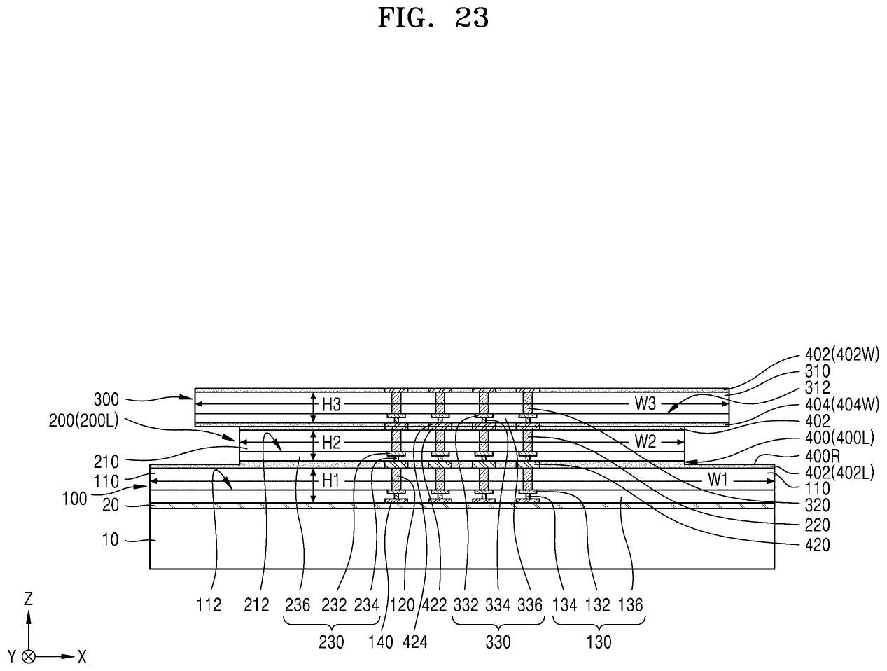

Referring to FIG. 23, the third semiconductor chip 300 may be on the second semiconductor chip 200. The second semiconductor chip 200 may be the lowermost second semiconductor chip 200L illustrated in FIG. 2. The third semiconductor chip 300 may be on the lowermost second semiconductor chip 200L such that the third wiring structure 330 faces the lowermost second semiconductor chip 200L. The third semiconductor chip 300 may be on the lowermost second semiconductor chip 200L such that the plurality of lower surface chip connection pads 424 formed on a lower surface of the third semiconductor chip 300 respectively correspond to the plurality of upper surface chip connection pads 422 formed on an upper surface of the lowermost second semiconductor chip 200L.

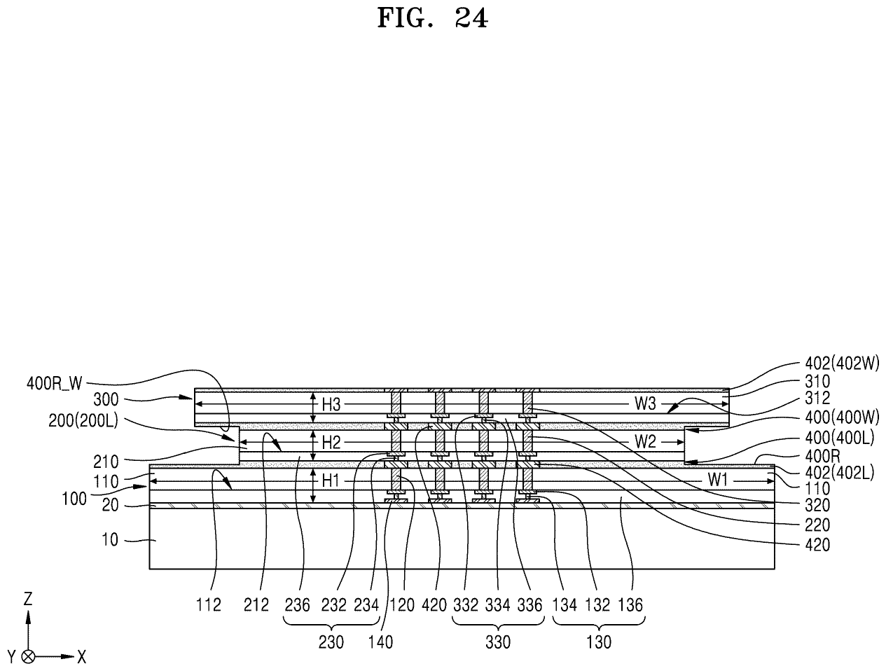

Subsequently, referring to FIG. 24, similar to the descriptions previously made with reference to FIGS. 21 and 22, heat and/or pressure may be applied while the third semiconductor chip 300 is placed on the lowermost second semiconductor chip 200L to bond the plurality of upper surface chip connection pads 422 respectively to the plurality of lower surface chip connection pads 424 and to bond the upper surface chip bonding insulating material layer 402 to the wide lower surface chip bonding insulating material layer 404W. Descriptions previously made with reference to FIGS. 21 and 22 may be omitted below.

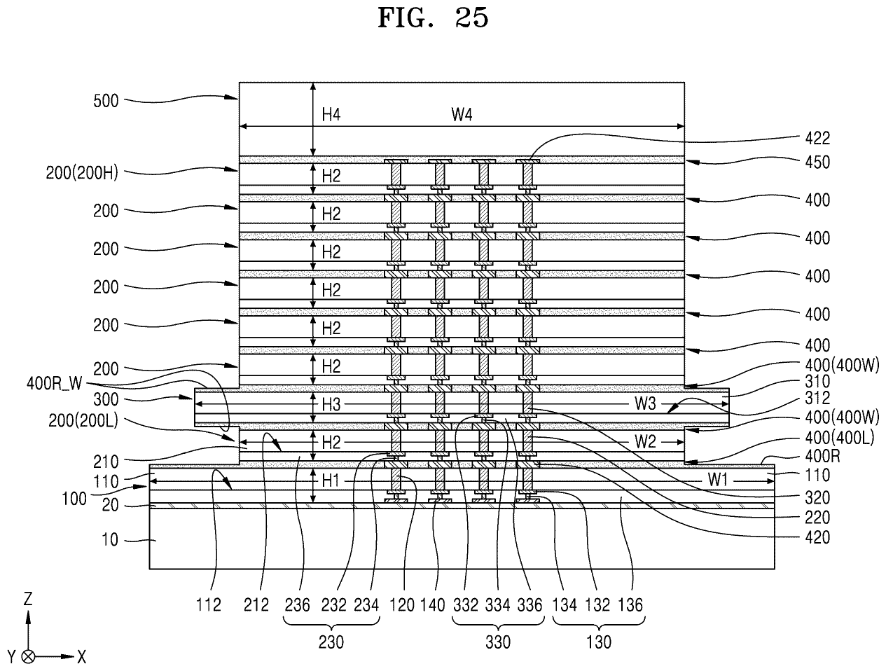

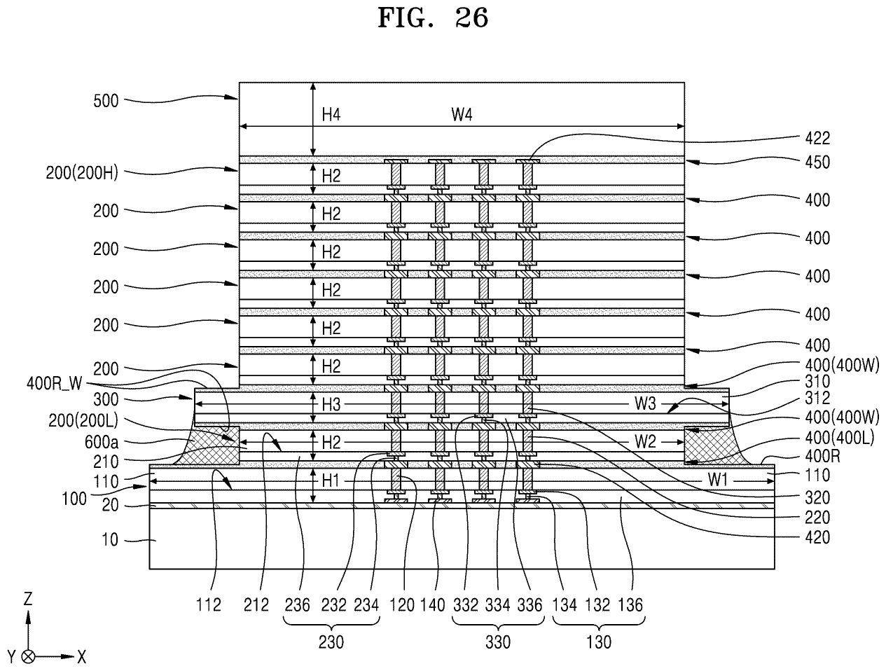

Thereafter, referring to FIGS. 25 and 26, the plurality of second semiconductor chips 200 may be sequentially placed on the third semiconductor chip 300. The plurality of lower surface chip connection pads 424 and the lower surface chip bonding insulating material layers 404 may be formed on lower surfaces of the plurality of second semiconductor chips 200 sequentially arranged on the third semiconductor chip 300, and the plurality of upper surface chip connection pads 422 and the upper surface chip bonding insulating material layers 402 may be formed on upper surfaces of the plurality of second semiconductor chips 200.

In addition, similar to the descriptions previously made with reference to FIGS. 21 and 22, the plurality of bonding pads 420 may be formed by bonding the plurality of upper surface chip connection pads 422 respectively to the plurality of lower surface chip connection pads 424 corresponding to each other between the plurality of second semiconductor chips 200, and the chip bonding insulating layer 400 may be formed by bonding the upper chip bonding insulating material layer 402 to the lower chip bonding insulating material layer 404 and, accordingly, the plurality of second semiconductor chips 200 may be sequentially attached onto the third semiconductor chip 300.

Thereafter, a side support layer 600a may be formed to seal a groove between the first semiconductor chip 100 and the third semiconductor chip 300. Because the method of forming the side support layer 600a is similar to the method of forming the side support layer 600a described above with reference to FIG. 15, redundant descriptions thereof may be omitted below.

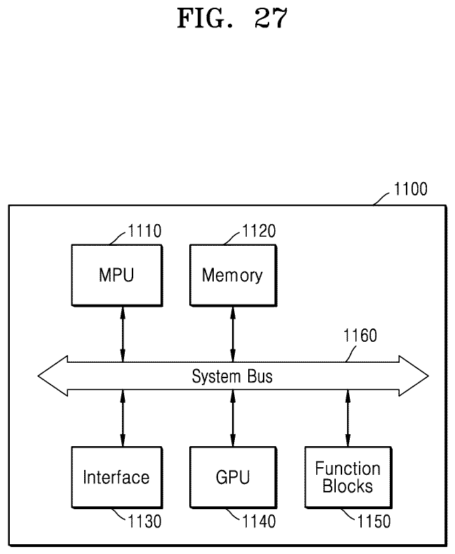

FIG. 27 is a block diagram schematically illustrating a configuration of a semiconductor package according to an embodiment.

Specifically, a semiconductor package 1100 may include a micro processing unit (MPU) 1110, a memory 1120, an interface 1130, a graphics processing unit (GPU) 1140, functional blocks 1150, and a bus 1160. The semiconductor package 1100 may include both the micro processing unit 1110 and the graphics processing unit 1140, or may include only one from among the micro processing unit 1110 and the graphics processing unit 1140.

The micro processing unit 1110 may include a core and an L2 cache. For example, the micro processing unit 1110 may include multiple cores. The multiple cores may have the same performance or different performances from each other. Also, the multiple cores may be activated at the same time or may be activated at different times from each other. The memory 1120 may store results of processing of the functional blocks 1150 under the control by the micro processing unit 1110. For example, when content stored in the L2 cache of the micro processing unit 1110 is flushed, the flushed content may be stored in the memory 1120. The interface 1130 may interface with external devices. For example, the interface 1130 may perform interface with a camera, a liquid crystal display (LCD), a speaker, and so on.

The graphics processing unit 1140 may perform graphics functions. For example, the graphics processing unit 1140 may perform video codec or may process three-dimensional (3D) graphics. The function blocks 1150 may perform various functions. For example, when the semiconductor package 1100 is an application processor (AP) used for a mobile device, some of the functional blocks 1150 may perform a communication function.

The semiconductor package 1100 may include any one of the semiconductor packages 10a, 10b, 10c, 10d, 20, 30, 40, 50, and 60 described above. The micro processing unit 1110 and/or the graphics processing unit 1140 may include any one of the semiconductor packages 10a, 10b, 10c, 10d, 20, 30, 40, 50, and 60 described above. The memory 1120 may include any one of the semiconductor packages 10a, 10b, 10c, 10d, 20, 30, 40, 50, and 60 described above. The interface 1130 and the functional blocks 1150 may include any one of the semiconductor packages 10a, 10b, 10c, 10d, 20, 30, 40, 50, and 60 described above.

A semiconductor package according to an embodiment of the present disclosure may include a first semiconductor chip, a plurality of second semiconductor chips, and a third semiconductor chip which are stacked and have substantially the same and relatively thin thickness (a vertical height) and are bonded to each other by hybrid bonding including diffusion bonding.

In this case, the third semiconductor chip has a horizontal width that is different from horizontal widths of the plurality of second semiconductor chips, and a side support layer seals a space formed due to the different horizontal widths. The side support layer may be attached to an upper surface of the first semiconductor chip and to the third semiconductor chip such that the plurality of second semiconductor chips and the third semiconductor chip are not separated from the first semiconductor chip despite warpage of the semiconductor package.

Effects of embodiments of the present disclosure are not limited to the effects described above, and effects embodiments of the present disclosure not described above will be clearly understood by those skilled in the art from the present specification and the accompanying drawings.

As described above, non-limiting example embodiments are disclosed in the drawings and specification. In the present specification, example embodiments are described by using specific terms, but the specific terms are merely used for the purpose of describing aspects of embodiments of the present disclosure and are not used to limit the meaning or scope of the present disclosure. Therefore, those skilled in the art will understand that various modifications and other equivalent embodiments may be made, and that such modifications and other equivalent embodiments are within the spirit and scope of the present disclosure.

While non-limiting example embodiments of the present disclosure have been described with reference to the accompanying drawings, it will be understood that various changes in form and details may be made therein without departing from the spirit and scope of the present disclosure.

What is claimed is:

1. A semiconductor package comprising:
a first semiconductor chip comprising a first semiconductor substrate and a plurality of first through-electrodes passing through the first semiconductor substrate;
a plurality of second semiconductor chips stacked on the first semiconductor chip, each of the plurality of second semiconductor chips comprising a second semiconductor substrate and a plurality of second through-electrodes passing through the second semiconductor substrate;
a third semiconductor chip between the first semiconductor chip and one of the plurality of second semiconductor chips, the third semiconductor chip comprising a third semiconductor substrate and a plurality of third through-electrodes passing through the third semiconductor substrate; and
a side support layer within a space between the third semiconductor chip and the first semiconductor chip,
wherein a first horizontal width of the third semiconductor chip is different from first horizontal widths of the plurality of second semiconductor chips.

2. The semiconductor package of claim 1, wherein the side support layer is on at least a part of a side surface of the third semiconductor chip.

3. The semiconductor package of claim 1, wherein the side support layer is not on a side surface of the third semiconductor chip.

4. The semiconductor package of claim 1, further comprising:
a lower chip bonding insulating layer on a lower surface of the third semiconductor chip,
wherein the side support layer is in contact with a lower surface of the lower chip bonding insulating layer.

5. The semiconductor package of claim 1, further comprising:
an upper chip bonding insulating layer on an upper surface of the third semiconductor chip,
wherein the side support layer is in contact with the upper chip bonding insulating layer.

6. The semiconductor package of claim 1, wherein the first horizontal width of the third semiconductor chip and the first horizontal widths of the plurality of second semiconductor chips are in a first horizontal direction, and
wherein a second horizontal width of the third semiconductor chip in a second horizontal direction perpendicular to the first horizontal direction is equal to second horizontal widths of the plurality of second semiconductor chips in the second horizontal direction.

7. The semiconductor package of claim 1, wherein the side support layer comprises a concave side surface.

8. The semiconductor package of claim 1, wherein, from a horizontal perspective, a longest horizontal width of the side support layer is less than a horizontal width of the first semiconductor chip and greater than the first horizontal widths of the plurality of second semiconductor chips and the first horizontal width of the third semiconductor chip.

9. The semiconductor package of claim 1, further comprising:
an additional third semiconductor chip comprising an additional third semiconductor substrate and a plurality of additional third through-electrodes passing through the additional third semiconductor substrate,
wherein another one of the plurality of second semiconductor chips is between the third semiconductor chip and the additional third semiconductor chip, and
wherein a first horizontal width of the additional third semiconductor chip is different from the first horizontal widths of the plurality of second semiconductor chips.

10. The semiconductor package of claim 1, further comprising a support dummy substrate on the plurality of second semiconductor chips.

11. A semiconductor package comprising:
a high bandwidth memory (HBM) control die comprising a first semiconductor substrate and a plurality of first through-electrodes passing through the first semiconductor substrate;
a plurality of first dynamic random access memory (DRAM) dies stacked on the HBM control die, each of the plurality of first DRAM dies comprising a second semiconductor substrate and a plurality of second through-electrodes passing through the second semiconductor substrate, and horizontal widths of the plurality of first DRAM dies are the same as each other;
a second DRAM die between the HBM control die and one of the plurality of first DRAM dies, the second DRAM die comprising a third semiconductor substrate and a plurality of third through-electrodes passing through the third semiconductor substrate, and a horizontal width of the second DRAM die is greater than the horizontal widths of the plurality of first DRAM dies;
a plurality of bonding pads between the HBM control die, each of the plurality of first DRAM dies, and the second DRAM die, and electrically connecting the plurality of first through-electrodes, the plurality of second through-electrodes, and the plurality of third through-electrodes to each other;
a plurality of chip bonding insulating layers surrounding the plurality of bonding pads and between the HBM control die, the plurality of first DRAM dies, and the second DRAM die; and
a side support layer on least a part of a side surface of the second DRAM die.

12. The semiconductor package of claim 11, wherein the side support layer is on at least a part of an upper surface of a chip bonding insulating layer, from among the plurality of chip bonding insulating layers, that is on an upper surface of the second DRAM die.

13. The semiconductor package of claim 11, wherein two of the plurality of first DRAM dies are between the HBM control die and the second DRAM die.

14. The semiconductor package of claim 11, wherein three of the plurality of first DRAM dies are between the HBM control die and the second DRAM die.

15. The semiconductor package of claim 11, wherein each of the plurality of bonding pads comprises a material comprising Cu, and
wherein each of the plurality of chip bonding insulating layers comprises silicon oxide.

16. The semiconductor package of claim 11, wherein the side support layer is not on a side surface of a first DRAM die, from among the plurality of first DRAM dies, that is on the second DRAM die.

17. The semiconductor package of claim 11, further comprising a package molding layer that surrounds the side support layer and the plurality of first DRAM dies in a horizontal direction.

18. A semiconductor package comprising:
a high bandwidth memory (HBM) control die comprising a first semiconductor substrate and a plurality of first through-electrodes passing through the first semiconductor substrate;
a plurality of first dynamic random access memory (DRAM) dies stacked on the HBM control die, each of the plurality of first DRAM dies comprising a second semiconductor substrate and a plurality of second through-electrodes passing through the second semiconductor substrate, and horizontal widths of the plurality of first DRAM dies are the same as each other;
a second DRAM die between the HBM control die and a lowermost first DRAM die among the plurality of first DRAM dies, the second DRAM die comprising a third semiconductor substrate and a plurality of third through-electrodes passing through the third semiconductor substrate, and a horizontal width of the second DRAM die is less than the horizontal widths of the plurality of first DRAM dies;
a plurality of bonding pads between the HBM control die, each of the plurality of first DRAM dies, and the second DRAM die, and electrically connecting the plurality of first through-electrodes, the plurality of second through-electrodes, and the plurality of third through-electrodes to each other;
a plurality of chip bonding insulating layers surrounding the plurality of bonding pads and between the HBM control die, the plurality of first DRAM dies, and the second DRAM die; and
a side support layer within a space between the lowermost first DRAM die and the HBM control die.

19. The semiconductor package of claim 18, wherein a vertical height of each of the plurality of first DRAM dies is 50 micrometers to 90 micrometers, and
wherein a vertical height of each of the plurality of chip bonding insulating layers is 100 nanometers to 1 micrometer.

20. The semiconductor package of claim 18, wherein the side support layer is in contact with a chip bonding insulating layer, from among the plurality of chip bonding insulating layers, that is on a lower surface of the lowermost first DRAM die.
